(19) United States
(12) Patent Application Publication
(10) Pub. No.: US 2025/0359334 A1
(43) Pub. Date: Nov. 20, 2025

(54) Array Substrate and Display Panel

(71) Applicants: BEIJING BOE TECHOLOGY DEVELOPMENT CO., LTD., Beijing (CN); BOE TECHNOLOGY GROUP CO., LTD., Chaoyang District, Beijimg (CN)

(72) Inventors: Shunhang Zhang, Beijing (CN); Zhenyu Zhang, Beijing (CN); Dongni Liu, Beijing (CN); Lianfu Yu, Beijing (CN); Zhen Zhang, Beijing (CN); Yunsik Im, Beijing (CN); Peirou Li, Beijing (CN)

(21) Appl. No.: 18/996,791

(22) PCT Filed: Apr. 26, 2024
(86) PCT No.: PCT/CN2024/090117

§ 371 Date: Jan. 17, 2025

(51) Int. Cl. H10D 86/40; G02F 1/1343; G02F 1/1362; G02F 1/1368

(52) U.S. Cl. CPC H10D 86/441; G02F 1/134309; G02F 1/136286; G02F 1/1368

(57) ABSTRACT

An array substrate includes a substrate, first electrodes, first signal lines and second signal lines. The first signal lines are arranged at intervals in a first direction, portions of a first signal line are bent in a second direction, and the first signal line includes first portions and second portions. A side of each pixel region is provided with a first portion of one first signal line, and another side of the pixel region is provided with a second portion of another first signal line; and a length of the first portion is greater than that of the second portion. In orthographic projections of the first electrode, the first portion and the second portion on the substrate, in the first direction, a distance between at least a portion of the first electrode and the first portion is not equal to a distance between the first electrode and the second portion.

### CROSS-REFERENCE TO RELATED APPLICATION

This application is the United States national phase of International Patent Application No. PCT/CN2024/090117, filed Apr. 26, 2024, the disclosure of which is hereby incorporated by reference in its entirety.

### BACKGROUND OF THE INVENTION

### Field of the Invention

The present disclosure relates to the field of display technologies, and in particular, to an array substrate and a display panel.

### Description of Related Art

With the continuous development of display technologies, display panels have been widely used, and people's requirements for display panels are getting higher and higher. High pixel density (pixels per inch, PPI) is an important development direction of display panels. Common display panels can include liquid crystal display (LCD) panels and organic light-emitting diode (OLED) display panels. Due to the simpler pixel circuit structure of the LCD panels (which can include a small number of thin film transistors and capacitors), the LCD panels have more advantages in ultra-high pixel density (for example, greater than or equal to 1000 PPI). As pixel density increases, the risk of pixel circuits being interfered (signal crosstalk) becomes greater and greater. Therefore, how to improve the stability of pixel circuits is an important technical issue faced in further increasing the pixel density of LCD panels.

### SUMMARY OF THE INVENTION

In an aspect, an array substrate is provided. The array substrate includes a substrate, and a plurality of first signal lines and a plurality of second signal lines located on a side of the substrate. The plurality of first signal lines and the plurality of second signal lines cross to define a plurality of pixel regions. The plurality of first signal lines are arranged at intervals in a first direction, portions of a first signal line are bent in a second direction, and the first signal line includes first portions and second portions. A side of each pixel region is provided with a first portion of one first signal line, another side of the pixel region is provided with a second portion of another first signal line, and a length of the first portion is greater than a length of the second portion. The first direction and the second direction intersect. The array substrate further includes a plurality of first electrodes corresponding to the plurality of pixel regions. At least a portion of a first electrode is located in a corresponding pixel region. In orthographic projections of the first electrode, the first portion and the second portion on the substrate, a distance between at least the portion of the first electrode and the first portion in the first direction is not equal to a distance between the first electrode and the second portion in the first direction.

In some embodiments, in the orthographic projections of the first electrode, the first portion and the second portion on the substrate, a length of a side, opposite to the first portion, of the first electrode is greater than a length of a side, opposite to the second portion, of the first electrode, and the distance between at least the portion of the first electrode and the first portion in the first direction is greater than the distance between the first electrode and the second portion in the first direction.

In some embodiments, the first signal line includes a plurality of first extension segments and a plurality of second extension segments that are alternately connected. The plurality of first extension segments extend in the first direction and are arranged at intervals in the second direction. The plurality of second extension segments extend in the second direction, and any two adjacent second extension segments in the plurality of second extension segments are connected to two ends of a first extension segment in the first direction. The first portion includes one second extension segment and two first extension segments connected to the second extension segment, and the second portion includes one second extension segment close to the first portion. The second extension segment included in the first portion is a first sub-segment, and the second extension segment included in the second portion is a second sub-segment. In orthographic projections of the first electrode, the first sub-segment and the second sub-segment on the substrate, a distance between at least the portion of the first electrode and the first sub-segment in the first direction is greater than a distance between at least the portion of the first electrode and the second sub-segment in the first direction.

In some embodiments, the array substrate further includes a plurality of first transistors, and a first transistor is electrically connected to one first electrode; a first electrode of the first transistor is electrically connected to the first signal line, and a second electrode of the first transistor is electrically connected to the first electrode. The first electrode includes a first sub-electrode, a second sub-electrode, and a third sub-electrode that are arranged in a direction away from the substrate; the first sub-electrode is electrically connected to the second electrode of the first transistor, the second sub-electrode is electrically connected to the first sub-electrode, and the third sub-electrode is electrically connected to the second sub-electrode. A distance between an orthographic projection of at least a portion of at least one of the first sub-electrode, the second sub-electrode and the third sub-electrode on the substrate and an orthographic projection of the first sub-segment on the substrate in the first direction is greater than a distance between the orthographic projection of at least the portion of the at least one of the first sub-electrode, the second sub-electrode and the third sub-electrode on the substrate and an orthographic projection of the second sub-segment on the substrate in the first direction.

In some embodiments, the first sub-electrode includes a third portion and a fourth portion, and the fourth portion is located on a side of the third portion in the second direction and is connected to the third portion. In orthographic projections of the third portion, the first sub-segment and the second sub-segment on the substrate, a distance between the third portion and the first sub-segment in the first direction is greater than a distance between the third portion and the second sub-segment in the first direction. An edge of the fourth portion close to the first sub-segment is flush with an edge of the third portion close to the first sub-segment, and an edge of the fourth portion close to the second sub-segment extends out of an edge of the third portion.

In some embodiments, an orthographic projection of the fourth portion on the substrate at least partially overlaps with the orthographic projection of the second sub-segment on the substrate.

In some embodiments, a distance between orthographic projections of the first sub-electrode and the first sub-segment on the substrate in the first direction is in a range of 0.5 μm to 1.5 μm; and/or a distance between orthographic projections of the third portion and the second sub-segment on the substrate in the first direction is in a range of 0.2 μm to 1 μm; and/or a dimension of a portion, whose orthographic projection on the substrate overlaps with the orthographic projection of the second sub-segment on the substrate, of the fourth portion in the first direction is in a range of 0.1 μm to 1 μm.

In some embodiments, the second sub-electrode includes a fifth portion and a sixth portion; the sixth portion is located on a side of the fifth portion in the second direction and is connected to the fifth portion, and two ends of the sixth portion in the first direction extend out of edges of the fifth portion. In orthographic projections of the fifth portion, the first sub-segment and the second sub-segment on the substrate, a distance between the fifth portion and the first sub-segment in the first direction is equal to a distance between the fifth portion and the second sub-segment in the first direction. A distance between an orthographic projection of the sixth portion on the substrate and the orthographic projection of the first sub-segment on the substrate in the first direction is greater than a distance between the orthographic projection of the sixth portion on the substrate and the orthographic projection of the second sub-segment on the substrate in the first direction.

In some embodiments, in the orthographic projections of the fifth portion, the first sub-segment and the second sub-segment on the substrate, the distance between the fifth portion and the first sub-segment in the first direction and the distance between the fifth portion and the second sub-segment in the first direction are both in a range of 1 μm to 2 μm; and/or the distance between orthographic projections of the sixth portion and the first sub-segment on the substrate in the first direction is in a range of 0.2 μm to 1 μm; and/or the distance between orthographic projections of the sixth portion and the second sub-segment on the substrate in the first direction is in a range of 0 to 1 μm.

In some embodiments, in orthographic projections of the third sub-electrode, the first sub-segment and the second sub-segment on the substrate, borders, close to each other, of the third sub-electrode and the first sub-segment are approximately parallel, and borders, close to each other, of the third sub-electrode and the second sub-segment are approximately parallel; and a distance between the third sub-electrode and the first sub-segment in the first direction is greater than a distance between the third sub-electrode and the second sub-segment in the first direction.

In some embodiments, the distance between orthographic projections of the third sub-electrode and the first sub-segment on the substrate in the first direction is in a range of 0.2 μm to 1 μm; and/or the distance between orthographic projections of the third sub-electrode and the second sub-segment on the substrate in the first direction is in a range of 0 to 1 μm.

In some embodiments, the array substrate further includes a first semiconductor layer, a first insulating layer, a first gate conductive layer, a second insulating layer, a source-drain conductive layer, a third insulating layer, a first planarization layer and a second planarization layer that are arranged in a direction away from the substrate. And the array substrate further includes first via holes penetrating through the first insulating layer and the second insulating layer and second via holes penetrating through the first insulating layer, the second insulating layer and the third insulating layer. The first transistor includes a first semiconductor pattern located in the first semiconductor layer and a first gate pattern located in the first gate conductive layer. The plurality of first signal lines are arranged in the source-drain conductive layer, and the first signal line passes through a first via hole to be electrically connected to the first semiconductor pattern. The first sub-electrode passes through a second via hole to be electrically connected to the first semiconductor pattern. The first planarization layer is disposed between the first sub-electrode and the second sub-electrode; first planarization layer includes third via holes, a third via hole exposes a portion of the first sub-electrode, and the second sub-electrode passes through the third via hole to be electrically connected to the first sub-electrode. The second planarization layer is disposed on a side of the second sub-electrode away from the substrate, and the second planarization layer covers a portion of the second sub-electrode located in the third via hole and exposes at least a portion of the second sub-electrode located on the first planarization layer. The third sub-electrode covers the second planarization layer and at least a portion of the second sub-electrode.

In some embodiments, polarities of voltage signals transmitted by two adjacent first signal lines are opposite.

In some embodiments, the array substrate further includes a first auxiliary layer. The first auxiliary layer is disposed between a layer where the plurality of first signal lines are located and a layer where the plurality of first electrodes are located. In orthographic projections of the first auxiliary layer, the first signal line and the first electrode on the substrate, the first auxiliary layer at least partially overlaps with the first signal line, and/or the first auxiliary layer at least partially overlaps with the first electrode.

In some embodiments, an orthographic projection of the first auxiliary layer on the substrate covers an orthographic projection of the first signal line on the substrate, and is non-overlapping with at least a portion of an orthographic projection of the first electrode on the substrate.

In some embodiments, the first signal line includes a plurality of first extension segments and a plurality of second extension segments that are alternately connected. The first auxiliary layer is of a grid structure, and the first auxiliary layer includes a plurality of first sub-portions, a plurality of second sub-portions and a plurality of grid holes. The plurality of first sub-portions extend in the second direction, and an orthographic projection of a first sub-portion on the substrate covers an orthographic projection of one second extension segment on the substrate. The plurality of second sub-portions extend in the first direction, and an orthographic projection of a second sub-portion on the substrate covers orthographic projections, on the substrate, of multiple first extension segments that are arranged in the first direction and in different first signal lines. In the plurality of grid holes, a grid hole corresponds to one pixel region, and the grid hole exposes at least a portion of the pixel region corresponding to the grid hole.

In some embodiments, the array substrate further includes a second electrode. The second electrode is disposed on a side of the first electrode away from the substrate, and the second electrode forms a storage capacitor with the first electrode. The first auxiliary layer and the second electrode transmit a same voltage signal.

In some embodiments, the orthographic projection of the first auxiliary layer on the substrate at least partially overlaps with an orthographic projection of the second electrode on the substrate.

In some embodiments, in orthographic projections of the second electrode and the first sub-portion on the substrate, the second electrode covers the first sub-portion, and there is an interval between a border of the second electrode and a border of the first sub-portion. The orthographic projection of the second electrode on the substrate partially overlaps with an orthographic projection of the second sub-portion on the substrate.

In some embodiments, a line width of the first signal line is in a range of 1 μm to 2 μm; and/or a dimension of the first sub-portion in the first direction is in a range of 1 μm to 2.5 μm; and/or a dimension of the second sub-portion in the second direction is in a range of 1 μm to 2 μm.

In some embodiments, the array substrate further includes a plurality of first transistors, and a first transistor is electrically connected to one first electrode; a first electrode of the first transistor is electrically connected to the first signal line, and a second electrode of the first transistor is electrically connected to the first electrode. The first electrode includes a fourth sub-electrode and a fifth sub-electrode arranged in sequence in a direction away from the substrate, the fourth sub-electrode is electrically connected to the second electrode of the first transistor, and the fifth sub-electrode is electrically connected to the fourth sub-electrode.

In some embodiments, the array substrate further includes a first semiconductor layer, a first insulating layer, a first gate conductive layer, a second insulating layer, a source-drain conductive layer, a third insulating layer, a first planarization layer, a fourth insulating layer and a second planarization layer that are arranged in a direction away from the substrate. And the array substrate further includes first via holes penetrating through the first insulating layer and the second insulating layer, and fourth via holes penetrating through the first insulating layer, the second insulating layer, the third insulating layer, the first planarization layer and the fourth insulating layer. The first transistor includes a first semiconductor pattern located in the first semiconductor layer and a first gate pattern located in the first gate conductive layer. The plurality of first signal lines are arranged in the source-drain conductive layer, and the first signal line passes through a first via hole to be electrically connected to the first semiconductor pattern. The fourth sub-electrode passes through a fourth via hole to be electrically connected to the first semiconductor pattern. The second planarization layer is disposed on a side of the fourth sub-electrode away from the substrate, and the second planarization layer covers a portion of the fourth sub-electrode in the fourth via hole and exposes at least a portion of the fourth sub-electrode on the fourth insulating layer. The first auxiliary layer is disposed between the first planarization layer and the fourth insulating layer, and the fifth sub-electrode covers the second planarization layer and at least a portion of the fourth sub-electrode.

In some embodiments, the array substrate further includes a plurality of first transistors, and a first transistor is electrically connected to one first electrode; a first electrode of the first transistor is electrically connected to the first signal line, and a second electrode of the first transistor is electrically connected to the first electrode. The array substrate further includes a plurality of compensation capacitors. At least a portion of a compensation capacitor is disposed on a side of the first transistor close to the substrate. A first electrode plate of the compensation capacitor is electrically connected to the second electrode of the first transistor, and a second electrode plate of the compensation capacitor is electrically connected to a constant voltage signal terminal.

In some embodiments, the array substrate further includes a second electrode disposed on a side of the first electrode away from the substrate, and the second electrode forms a storage capacitor with the first electrode. The second electrode plate of the compensation capacitor transmits a same voltage signal as the second electrode.

In some embodiments, the array substrate includes a display region and a peripheral region, and the plurality of first transistors are disposed in the display region. The array substrate further includes a second semiconductor layer and a second gate layer arranged in a direction away from the substrate. The second semiconductor layer and the second gate layer are located on a side of the plurality of first transistors close to the substrate. The array substrate further includes second transistors disposed in the peripheral region, and a second transistor includes a second semiconductor pattern located in the second semiconductor layer and a second gate pattern located in the second gate layer. The first electrode plate of the compensation capacitor is located in the second semiconductor layer, and the second electrode plate of the compensation capacitor is located in the second gate layer.

In some embodiments, the first transistors are oxide thin film transistors; and/or the second transistors are low temperature polysilicon thin film transistors.

In some embodiments, the second electrode plate of the compensation capacitor extends in the first direction, and an orthographic projection of the second electrode plate on the substrate at least partially overlaps with an orthographic projection of a second signal line on the substrate.

In some embodiments, a dimension of the second signal line in the second direction is in a range of 1 μm to 2 μm; and/or a dimension of the second electrode plate in the second direction is in a range of 1 μm to 3 μm.

In another aspect, a display panel is provided. The display panel includes an opposite substrate, a liquid crystal layer, and the array substrate as described in any one of the above embodiments. The opposite substrate is disposed opposite to the array substrate, and the liquid crystal layer is disposed between the array substrate and the opposite substrate.

In still yet another aspect, a display device is provided. The display device includes the array substrate as described in any one of the above embodiments, or the display panel as described in the above embodiments.

### BRIEF DESCRIPTION OF THE DRAWINGS

In order to describe technical solutions in the present disclosure more clearly, accompanying drawings to be used in some embodiments of the present disclosure will be introduced briefly below. Obviously, the accompanying drawings to be described below are merely accompanying drawings of some embodiments of the present disclosure, and a person of ordinary skill in the art can obtain other drawings according to these drawings In addition, the accompanying drawings to be described below may be regarded as schematic diagrams, and are not limitations on actual sizes of products, actual processes of methods and actual timings of signals involved in the embodiments of the present disclosure.

FIG. 1 is a structural diagram of a display device, in accordance with some embodiments;

FIG. 2 is a structural diagram of another display device, in accordance with some embodiments;

FIG. 3 is a structural diagram showing a layout of an array substrate, in accordance with some embodiments;

FIG. 4 is a structural diagram showing a layout of first signal lines, second signal lines and first electrodes, in accordance with some embodiments;

FIG. 5 is a partial enlarged view of the region A in FIG. 4;

FIG. 6 is an equivalent circuit diagram of an array substrate, in accordance with some embodiments;

FIG. 7 is a structural diagram of a single pixel region, in accordance with some embodiments;

FIG. 8 is a sectional view taken along the section line A-A in FIG. 3;

FIG. 9 is a structural diagram of a first sub-electrode, in accordance with some embodiments;

FIG. 10 is another structural diagram of a first sub-electrode, in accordance with some embodiments;

FIG. 11 is a structural diagram of a second sub-electrode, in accordance with some embodiments;

FIG. 12 is a structural diagram of a third sub-electrode, in accordance with some embodiments;

FIG. 13 is a structural diagram showing a layout of an array substrate, in accordance with some embodiments;

FIG. 14 is a sectional view taken along the section line B-B in FIG. 13;

FIG. 15 is a structural diagram showing a first auxiliary layer, first signal lines and first electrodes, in accordance with some embodiments;

FIG. 16 is a partial enlarged view of the region C in FIG. 15;

FIG. 17 is a sectional view taken along the section line C-C in FIG. 13;

FIG. 18 is a sectional view taken along the section line D-D in FIG. 13;

FIG. 19 is a sectional view taken along the section line E-E in FIG. 13;

FIG. 20 is a sectional view showing a structure of an array substrate, in accordance with some embodiments;

FIG. 21 is a sectional view showing another structure of an array substrate, in accordance with some embodiments; and

FIG. 22 is a structural diagram of compensation capacitors and first transistors, in accordance with some embodiments.

### DESCRIPTION OF THE INVENTION

Technical solutions in some embodiments of the present disclosure will be described clearly and completely below with reference to the accompanying drawings. Obviously, the described embodiments are merely some but not all embodiments of the present disclosure. All other embodiments obtained by a person of ordinary skill in the art based on the embodiments of the present disclosure shall be included in the protection scope of the present disclosure.

Unless the context requires otherwise, throughout the description and the claims, the term “comprise” and other forms thereof such as the third-person singular form “comprises” and the present participle form “comprising” are construed as open and inclusive meaning, i.e., “including, but not limited to”.

In the description of the specification, the terms such as “one embodiment”, “some embodiments”, “exemplary embodiments”, “example”, “specific example” or “some examples” are intended to indicate that specific features, structures, materials or characteristics related to the embodiment(s) or example(s) are included in at least one embodiment or example of the present disclosure. Schematic representations of the above terms do not necessarily refer to the same embodiment(s) or example(s). In addition, the specific features, structures, materials or characteristics may be included in any one or more embodiments or examples in any suitable manner.

In the present disclosure, terms such as “lower”, “below”, “above”, and “upper” are used to explain association relationships of components shown in the drawings. The terms may be relative concepts and described based on directions shown in the drawings, or described based on an order in which process steps are formed, which are not limited.

It will be understood that, in a case where a layer or element is referred to be on another layer or substrate, it may be that the layer or element is directly on the another layer or substrate, or it may be that intervening layer(s) exist between the layer or element and the another layer or substrate.

The term “opposite” means that a first element may be directly or indirectly opposite to a second element. In a case where a third element is between the first element and the second element, the first element and the second element may be understood as being indirectly opposite to each other although still opposite to each other.

Hereinafter, the terms “first” and “second” are used for descriptive purposes only, and are not to be construed as indicating or implying the relative importance or implicitly indicating the number of indicated technical features. Thus, a feature defined with “first” or “second” may explicitly or implicitly include one or more of the features. In the description of the embodiments of the present disclosure, the term “a/the plurality of” means two or more unless otherwise specified.

In the description of some embodiments, the terms such as “coupled” and “connected” and derivatives thereof may be used. The term “connected” should be understood in a broad sense. For example, the term “connected” may represent a fixed connection, or a detachable connection, or a one-piece connection; alternatively, the term “connected” may represent a direct connection, or an indirect connection through an intermediate medium. The term “coupled”, for example, indicates that two or more components are in direct physical or electrical contact. The term “coupled” may also indicate that two or more components are not in direct contact with each other, but still cooperate or interact with each other. The embodiments disclosed herein are not necessarily limited to the context herein.

The phrase “at least one of A, B and C” has a same meaning as the phrase “at least one of A, B or C”, and they both include the following combinations of A, B and C: only A, only B, only C, a combination of A and B, a combination of A and C, a combination of B and C, and a combination of A, B and C.

The phrase “A and/or B” includes the following three combinations: only A, only B, and a combination of A and B.

The phrase “applicable to” or “configured to” as used herein indicates an open and inclusive expression, which does not exclude devices that are applicable to or configured to perform additional tasks or steps.

In addition, the phrase “based on” as used herein is meant to be open and inclusive, since a process, step, calculation or other action that is “based on” one or more of the stated conditions or values may, in practice, be based on additional conditions or values beyond those stated.

As used herein, the term such as “about”, “substantially” or “approximately” includes a stated value and an average value within an acceptable range of deviation of a particular value. The acceptable range of deviation is determined by a person of ordinary skill in the art in view of measurement in question and errors associated with the measurement of a particular quantity (i.e., the limitation of the measurement system).

As used herein, the term such as “parallel”, “perpendicular”, or “equal” includes a stated condition and a condition similar to the stated condition. A range of the similar condition is in an acceptable range of deviation, and the acceptable range of deviation is determined by a person of ordinary skill in the art in view of measurement in question and errors associated with the measurement of a particular quantity (i.e., the limitation of the measurement system). For example, the term “parallel” includes absolute parallelism and approximate parallelism, and an acceptable range of deviation of the approximate parallelism may be, for example, a deviation within 5°. The term “perpendicular” includes absolute perpendicularity and approximate perpendicularity, and an acceptable range of deviation of the approximate perpendicularity may also be, for example, a deviation within 5°. The term “equal” includes absolute equality and approximate equality, and an acceptable range of deviation of the approximate equality may be, for example, a difference between two equals being less than or equal to 5% of any one of the two equals.

Exemplary embodiments are described herein with reference to sectional views and/or plan views as idealized exemplary drawings. In the drawings, thicknesses of layers and sizes of regions are enlarged for clarity. Variations in shapes relative to the accompanying drawings due to, for example, manufacturing technologies and/or tolerances may be envisaged. Therefore, the exemplary embodiments should not be construed as being limited to the shapes of the regions shown herein, but including shape deviations due to, for example, manufacturing. For example, an etched region shown to have a rectangular shape generally has a feature of being curved. Therefore, the regions shown in the accompanying drawings are schematic in nature, and their shapes are not intended to show actual shapes of regions in devices, and are not intended to limit the scope of the exemplary embodiments.

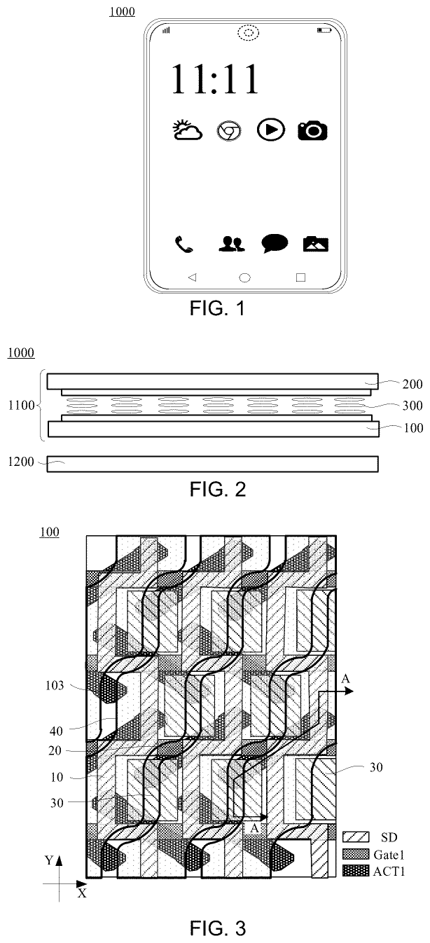

Referring to FIG. 1, embodiments of the present disclosure provide a display device 1000, and the display device 1000 is a product with an image display function. For example, the display device 1000 is any device that displays images whether in motion (e.g., videos) or stationary (e.g., static images), and whether textual or graphical.

For example, the display device 1000 is a television, a laptop computer, a tablet computer, a personal digital assistant (PDA), a mobile phone (a mobile phone), a watch, a clock, a calculator, a global positioning system (GPS) receiver/navigator, a camera, a camera view display (e.g., a rear-view camera display in a vehicle), a wearable device, an augmented reality (AR) device, a virtual reality (VR) device, a mixed reality (MR) device, a vehicle-mounted display, a flight display, or any other product or component with a display function.

In some embodiments, from a perspective of a light-emitting type of the display device 1000, the display device 1000 can be a liquid crystal display (LCD). From a perspective of a form of the display device 1000, the display device 1000 can be a planar display device or a curved display device. From a perspective of a shape of the display device 1000, the display device 1000 can be rectangular or circular. Some embodiments of the present disclosure are schematically described below by taking an example where the display device is a rectangular and planar liquid crystal display, but the implementation of the present disclosure is not limited to this, and any other display device can also be considered as long as the same technical concept is applied.

In some embodiments, the display device 1000 includes a display panel 1100 and a driving circuit board. The driving circuit board may include driving circuits such as a timing controller (TCON), a power management chip DC/DC, and an adjustable resistance voltage division circuit (for generating Vcom signal). The driving circuit board may further include other circuit structures, which will not be listed here one by one. The driving circuit board is electrically connected to the display panel 1100, and is used for transmitting control signals to the display panel 1100, so as to drive the display panel 1100 to perform image display. In addition, the display device 1000 may further include a touch structure, an under-screen camera, and an under-screen fingerprint recognition sensor, and thus the display device 1000 is able to implement various functions such as touch, taking pictures, video recording, and fingerprint recognition, which is not specifically limited here.

In some embodiments, referring to FIG. 2, in the case where the display device 1000 is a liquid crystal display, the display device 1000 can further include a backlight source 1200 disposed on a backlight side of the display panel 1100. For example, the backlight source 1200 can be a direct-lit backlight source or an edge-lit backlight source. The backlight source 1200 is used to provide light for the display panel 1100. The display panel 1100 includes a plurality of sub-pixels, and each sub-pixel can adjust an amount of light passing through the display panel 1100. Thus, each sub-pixel can display a same or different gray scale, thereby achieving the purpose of image display.

Referring to FIG. 2, in the case where the display panel 1100 is a liquid crystal display panel, the display panel 1100 can include an array substrate 100 and an opposite substrate 200 that are disposed opposite to each other, and a liquid crystal layer 300 disposed between the array substrate 100 and the opposite substrate 200. The opposite substrate 200 may also be referred to as a color filter substrate or an encapsulation substrate. The opposite substrate 200 can filter light entering the opposite substrate 200, so that each sub-pixel can emit light of one color (e.g., red, green or blue), and different sub-pixels can emit light of the same or different colors. Thus, the display panel 1100 can achieve color display. Of course, the structure of the display panel 1100 is not limited thereto, and the display panel 1100 may further include other structures as long as the same technical concept is adopted. For example, the display panel 1100 may further include a first alignment film (not shown in the figure) disposed on a side of the array substrate 100 proximate to the liquid crystal layer 300, and a second alignment film (not shown in the figure) disposed on a side of the opposite substrate 200 proximate to the liquid crystal layer 300.

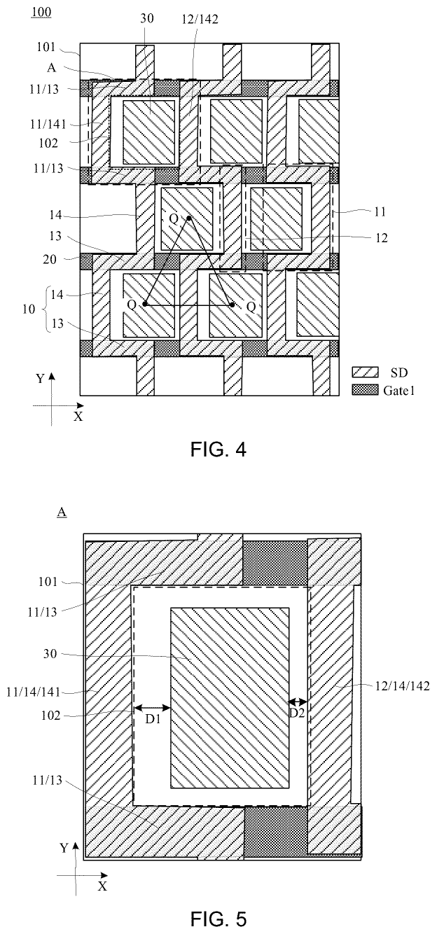

In some embodiments, referring to FIGS. 3 and 4, the array substrate 100 includes a plurality of first signal lines 10 and a plurality of second signal lines 20, and the plurality of first signal lines 10 and the plurality of second signal lines 20 cross to define a plurality of pixel regions 102. The plurality of first signal lines 10 are arranged at intervals in a first direction X, and the plurality of second signal lines 20 are arranged at intervals in a second direction Y. The plurality of first signal lines 10 and the plurality of second signal lines 20 can be located in different conductive layers, so that the plurality of first signal lines 10 and the plurality of second signal lines 20 are insulated from each other to avoid short circuit between the first signal lines 10 and the second signal lines 20. Orthographic projections of the plurality of first signal lines 10 on the substrate 101 intersect orthographic projections of the plurality of second signal lines 20 on the substrate 101 to form a plurality of squares, and each square defines a single pixel region 102.

For example, the first signal line 10 is a data line for transmitting a data signal, and the second signal line 20 is a scan signal line for transmitting a scan signal (for controlling whether the first transistor T1 described below is turned on). Of course, the embodiments of the present disclosure are not limited thereto, and the first signal line 10 and the second signal line 20 may also be used to transmit other signals as long as the same technical concept is adopted.

As shown in FIG. 4, the plurality of first signal lines 10 are arranged at intervals in the first direction X, and portions of the first signal line 10 are bent in the second direction Y. In other words, the first signal lines 10 extend in a broken line, and the first signal lines 10 are broken lines. In this way, centers Q of two pixel regions 102 that are located between the same two first signal lines 10 and adjacent in the second direction Y are staggered in the first direction X. For example, lines connecting centers of three nearest pixel regions 102 constitute a triangle. That is, the multiple pixel regions 102 are arranged in a delta staggered manner. In this way, it may be possible to increase the density of the pixel regions 102 in the array substrate 100, thereby increasing the pixel density of the display panel.

Referring to FIGS. 4 and 5, the first signal line 10 includes first portions 11 and second portions 12. A side of each pixel region 102 is provided with a first portion 11 of a first signal line 10, and another side of the pixel region 102 is provided with a second portion 12 of another first signal line 10. In other words, the first portion 11 and the second portion 12 that respectively belong to two adjacent first signal lines 10 surround one pixel region 102. Since the portions of the first signal line 10 are bent in the second direction Y, a length of the first portion 11 is greater than that of the second portion 12. That is, lengths of portions of the two first signal lines 10 surrounding the same pixel region 102 are different.

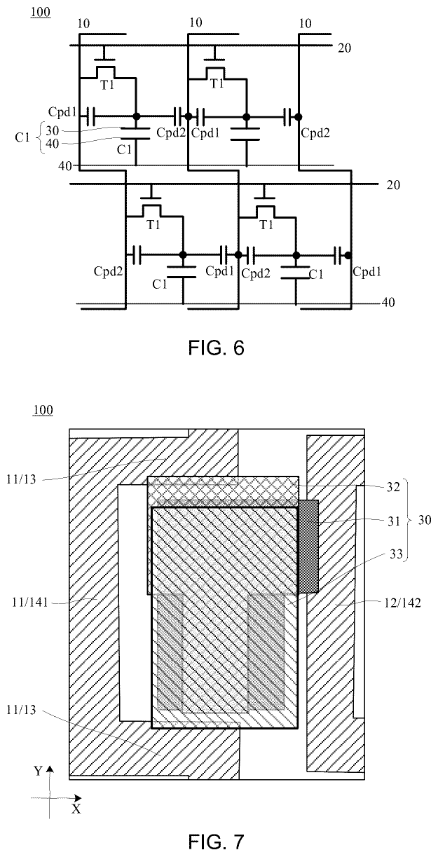

In some embodiments, referring to FIG. 6, the array substrate 100 further includes a plurality of pixel circuits, and the pixel circuit can include at least one thin film transistor (TFT) and at least one capacitor. For example, the pixel circuit is a “1T1C” circuit, a “2T1C” circuit, a “3T1C” circuit, or the like. Here, “T” represents a thin film transistor, the number before “T” represents the number of thin film transistors, “C” represents a capacitor, and the number before “C” represents the number of capacitors.

In the following embodiments of the present disclosure, an exemplary description is made for the embodiments of the present disclosure by taking an example where the pixel circuit is the “1T1C” circuit, but the embodiments of the present disclosure are not limited to this, and any other pixel circuit can also be considered as long as the same technical concept is applied. In the case where the pixel circuit is the “1T1C” circuit, the pixel circuit includes a first transistor T1 and a storage capacitor C1.

A control electrode (gate) of the first transistor T1 is connected to the second signal line 20, or a portion of the second signal line 20 directly forms the control electrode of the first transistor T1; a first electrode (one of a source and a drain) of the first transistor T1 is electrically connected to the first signal line 10; and a second electrode (the other of the source and the drain) of the first transistor T1 is electrically connected to an electrode plate of the storage capacitor C1. For example, referring to FIG. 3, the second signal line 20 extends in the first direction X, and is configured to form gates of multiple first transistors T1 arranged in the first direction X.

In some embodiments, the first transistor T1 can be an oxide thin film transistor (OTFT). In this way, it may be possible to reduce the leakage current of the first transistor T1, and increase the aperture ratio of the pixel region, thereby increasing the light transmittance of the array substrate 100. For example, the first transistor T1 includes a first semiconductor pattern 103, and a material of the first semiconductor pattern 103 includes indium gallium zinc oxide (IGZO).

Referring to FIGS. 3 and 6, the array substrate 100 further includes a plurality of first electrodes 30 and a second electrode 40. At least a portion of the first electrode 30 and the second electrode 40 are arranged opposite to each other to form the storage capacitor C1; and the first electrode 30 forms one electrode plate of the storage capacitor C1, and the second electrode 40 forms the other electrode plate of the storage capacitor C1. For example, one of the first electrode 30 and the second electrode 40 is a pixel electrode, and the other of the first electrode 30 and the second electrode 40 is a common electrode. For example, the first electrode 30 is the pixel electrode, and the second electrode 40 is the common electrode.

For example, the second electrode of the first transistor T1 is electrically connected to the electrode plate of the storage capacitor C1 formed by the first electrode 30, and the electrode plate of the storage capacitor C1 formed by the second electrode 40 can be electrically connected to a constant voltage signal terminal (e.g., a common voltage signal terminal). The first transistor T1 is configured to transmit the data signal from the first signal line 10 to the first electrode 30 (i.e., transmit the data signal to one electrode plate of the storage capacitor C1) under the control of the second signal line 20.

In some embodiments, referring to FIGS. 5 and 6, at least a portion of the first electrode 30 is arranged in the pixel region 102. That is, at least a portion of the first electrode 30 is arranged between the first portion 11 and the second portion 12. As the pixel density of the display panel increases, an area of the pixel region 102 in the array substrate 100 gradually decreases, and distances between the first electrode 30 and an adjacent first portion 11 and between the first electrode 30 and an adjacent second portion 12 become smaller and smaller, which results in formation of parasitic capacitors between the first electrode 30 and the first portion 11 and between the first electrode 30 and the second portion 12. In the embodiments of the present disclosure, the parasitic capacitor formed between the first electrode 30 and the first portion 11 is a first parasitic capacitor Cpd1, and the parasitic capacitor formed between the first electrode 30 and the second portion 12 is a second parasitic capacitor Cpd2.

In some embodiments, the array substrate provided in the present disclosure can be used to form a display panel with the pixel density greater than or equal to 1000 PPI. For example, the array substrate 100 is used to form a display panel with the pixel density of 1000 PPI, 1200 PPI, 2000 PPI or 2117 PPI, or with a higher pixel density. Of course, the application scope of the array substrate 100 provided in the embodiments of the present disclosure is not limited thereto, and display panels with other pixel densities can be considered as long as the same technical concept is adopted. In the following embodiments of the present disclosure, an exemplary description is made for the embodiments of the present disclosure by taking an example where the array substrate 100 is configured to form the display panel with 2117 PPI. For example, the descriptions for a size of a structure of the array substrate 100 and a distance between two structures of the array substrate 100 are based on the display panel with 2117 PPI.

A voltage generated by the coupling of the first parasitic capacitor Cpd1 and the first electrode 30 is ΔV1, and

$$Δ V 1 = \frac{Cpd 1}{Cpd 1 + C 1} \times Δ Vdata 1 ;$$

a voltage generated by the coupling of the second parasitic capacitor Cpd2 and the first electrode 30 is ΔV2, and

$$Δ V 2 = \frac{Cpd 2}{Cpd 2 + C 1} \times Δ Vdata 2.$$

αVdata1 refers to an amount of voltage change of the first signal line 10 (the first signal line 10 where the first portion 11 is located) for forming the first parasitic capacitor Cpd1, and ΔVdata2 refers to an amount of voltage change of the first signal line 10 (the first signal line 10 where the second portion 12 is located) for forming the second parasitic capacitor Cpd2. A voltage generated by the coupling of the first electrode 30 with both the first parasitic capacitor Cpd1 and the second parasitic capacitor Cpd2 is ΔV, and ΔV=ΔV1+ΔV2. It can be seen that the voltage generated by the coupling of the first electrode 30 with the two adjacent first signal lines 10 (the first portion 11 and the second portion 12) is ΔV, which is positively correlated with the magnitudes of the capacitances of the first parasitic capacitor Cpd1 and the second parasitic capacitor Cpd2, and negatively correlated with the magnitude of the capacitance of the storage capacitor C1.

In some embodiments, polarities of voltage signals (e.g., data signals) transmitted by two adjacent first signal lines 10 are opposite. That is, a voltage value of the data signal transmitted by one of the two adjacent first signal lines 10 is a positive voltage, and a voltage value of the data signal transmitted by the other one of the two adjacent first signal lines 10 is a negative voltage. In other words, the plurality of first signal lines 10 adopt a column inversion driving manner. In this way, for ΔV1 and ΔV2, one is positive and the other one is negative, which is beneficial to reducing the voltage (ΔV) generated by the coupling of the first electrode 30 with both the first parasitic capacitor Cpd1 and the second parasitic capacitor Cpd2, thereby reducing the voltage fluctuation of the first electrode 30 (i.e., helping improve the voltage stability of the first electrode 30). Thus, the fluctuation of the electric field formed between the first electrode 30 and the second electrode 40 may be reduced, which is beneficial to reducing the risk of change in the deflection direction of the liquid crystal molecules in the liquid crystal layer in the same display phase (within a frame), and ensures the stability of the optical rotation direction of the liquid crystal molecules in the pixel region, thereby reducing the fluctuation of the light transmittance of the display panel, improving the stability of the gray scale displayed by the sub-pixel, and improving the display quality of the display panel.

In the related art, the first electrode 30 is usually disposed in the middle of two adjacent first signal lines 10. That is, distances between the first electrode 30 and both the first portion 11 and the second portion 12 in the first direction are substantially equal. The length of the first portion 11 is greater than that of the second portion 12, and a length of a side of the first electrode 30 adjacent to the first portion 11 is greater than that of a side of the first electrode 30 adjacent to the second portion 12. Therefore, in the case where the distances between the first electrode 30 and both the first portion 11 and the second portion 12 are equal, the capacitance of the first parasitic capacitor Cpd1 formed between the first electrode 30 and the first portion 11 is greater than the capacitance of the second parasitic capacitor Cpd2 formed between the first electrode 30 and the second portion 12 (i.e., Cpd1>Cpd2). In this case, the voltage generated by the coupling of the first electrode 30 with both the first parasitic capacitor Cpd1 and the second parasitic capacitor Cpd2 is ΔV=ΔV1+ΔV2≠0. That is, the voltage signals transmitted on the first signal lines 10 will cause crosstalk to the voltage on the first electrode 30, resulting in the fluctuation of the voltage on the first electrode 30. Furthermore, the voltage fluctuation of the first electrode 30 can affect the voltage difference between the first electrode 30 and the second electrode 40, thereby causing the deflection direction of the liquid crystal molecules in the liquid crystal layer to change within a display period, causing the gray scale displayed by the sub-pixel to deviate, and reducing the display quality of the display panel.

In order to solve the above technical problems, in the array substrate provided in the embodiments of the present disclosure, referring to FIGS. 4 and 5, for at least one pixel region 102, in orthographic projections of the first electrode 30, the first portion 11 and the second portion 12 on the substrate 101, a distance D1 between at least a portion of the first electrode 30 and the first portion 11 in the first direction X is not equal to a distance D2 between the first electrode 30 and the second portion 12 in the first direction X. In this way, it may be possible to balance the capacitance of the first parasitic capacitor Cpd1 formed between the first electrode 30 and the first portion 11 as well as the capacitance of the second parasitic capacitor Cpd2 formed between the first electrode 30 and the second portion 12, to reduce the capacitance difference between the first parasitic capacitor Cpd1 and the second parasitic capacitor Cpd2, and to reduce the voltage (ΔV) generated by the coupling of the first electrode 30 with both the first parasitic capacitor Cpd1 and the second parasitic capacitor Cpd2. Based on this, it may be possible to reduce the voltage fluctuation of the first electrode 30 within a display period, and to improve the stability of the voltage difference between the first electrode 30 and the second electrode 40 within the display period. Thus, the electric field formed between the first electrode 30 and the second electrode 40 is more stable, which is beneficial to reducing the change in the deflection direction of the liquid crystal molecules in the liquid crystal layer in the same display phase (within a frame), ensures the stability of the optical rotation direction of the liquid crystal molecules in the pixel region, reduces the fluctuation of the light transmittance of the display panel, and improves the display quality of the display panel.

For example, for each pixel region 102, in the orthographic projections of the first electrode 30, the first portion 11 and the second portion 12 on the substrate 101, the distance D1 between at least a portion of the first electrode 30 and the first portion 11 in the first direction X is not equal to the distance D2 between the first electrode 30 and the second portion 12 in the first direction X.

In some embodiments, referring to FIGS. 4 and 5, the length of the first portion 11 is greater than the length of the second portion 12; and in the orthographic projections of the first electrode 30, the first portion 11 and the second portion 12 on the substrate 101, a length of a side, opposite to the first portion 11, of the first electrode 30 is greater than a length of a side, opposite to the second portion 12, of the first electrode 30. Based on this, a facing area of the first electrode 30 and the first portion 11 is greater than a facing area of the first electrode 30 and the second portion 12.

For example, as shown in FIG. 5, the side of the first electrode 30 opposite to the first portion 11 includes a left side of the first electrode 30, a portion of an upper side of the first electrode 30, and a portion of a lower side of the first electrode 30, and the side of the first electrode 30 opposite to the second portion 12 includes a right side of the first electrode 30. Obviously, the length of the side of the first electrode 30 opposite to the first portion 11 is greater than the length of the side of the first electrode 30 opposite to the second portion 12.

The magnitudes of the parasitic capacitances formed between the first electrode 30 and both the first portion 11 and the second portion 12 are positively correlated with the facing area of the first electrode 30 and the first portion 11 as well as the facing area of the first electrode 30 and the second portion 12 respectively, and negatively correlated with the distances between the first electrode 30 and both the first portion 11 and the second portion 12 respectively. In the case where the length of the first portion 11 is greater than the length of the second portion 12, the facing area of the first electrode 30 and the first portion 11 is greater than the facing area of the first electrode 30 and the second portion 12. The distance D1 between at least a portion of the first electrode 30 and the first portion 11 in the first direction X is greater than the distance D2 between the first electrode 30 and the second portion 12 in the first direction X, which may balance the capacitance of the first parasitic capacitor Cpd1 formed between the first electrode 30 and the first portion 11 as well as the capacitance of the second parasitic capacitor Cpd2 formed between the first electrode 30 and the second portion 12, and reduce the capacitance difference between the first parasitic capacitor Cpd1 and the second parasitic capacitor Cpd2, thereby reducing the voltage (ΔV) generated by the coupling of the first electrode 30 with both the first parasitic capacitor Cpd1 and the second parasitic capacitor Cpd2, and reducing the voltage fluctuation of the first electrode 30. In this way, it may be possible to improve the stability of the voltage difference between the first electrode 30 and the second electrode 40, so as to provide a more stable electric field. Moreover, it may be possible to reduce the change in the deflection direction of the liquid crystal molecules in the liquid crystal layer in the same display phase (within a frame), and reduce the fluctuation of the light transmittance (gray scale) of the display panel, thereby improving the display quality of the display panel.

In some embodiments, referring to FIGS. 4 and 5, the first signal line 10 includes a plurality of first extension segments 13 and a plurality of second extension segments 14 that are alternately connected. The plurality of first extension segments 13 extend in the first direction X and are arranged at intervals in the second direction Y. The plurality of second extension segments 14 extend in the second direction Y, and any two adjacent second extension segments 14 in the plurality of second extension segments 14 are connected to two ends of a first extension segment 13 in the first direction X.

For the same pixel region 102, the first portion 11 includes one second extension segment 14 and two first extension segments 13 connected to the second extension segment 14, and the second portion 12 includes one second extension segment 14 close to the first portion 11. In the following embodiments of the present disclosure, for the convenience of description, the second extension segment 14 included in the first portion 11 is referred to as a first sub-segment 141, and the second extension segment 14 included in the second portion 12 is referred to as a second sub-segment 142.

It should be noted that, as shown in FIG. 4, there is one pixel region 102 on each of two sides of the second extension segment 14 in the first direction X. For two pixel regions 102 that are adjacent in the first direction X, the second extension segment 14 located between the two pixel regions 102 can serve as the first sub-segment 141 and the second sub-segment 142 of the two pixel regions 102. For example, for a first row of pixel regions 102 in FIG. 4, the second extension segment 14 located between two pixel regions 102 serves as the second sub-segment 142 of a left pixel region 102 and also serves as the first sub-segment 141 of a right pixel region 102. For a second row of pixel regions 102 in FIG. 4, the second extension segment 14 located between two pixel regions 102 serves as the first sub-segment 141 of a left pixel region 102 and also serves as the second sub-segment 142 of a right pixel region 102. In the following embodiments of the present disclosure, unless otherwise specified, the descriptions of the first electrode 30, the first sub-segment 141 and the second sub-segment 142 are all based on the first electrode 30, the first sub-segment 141 and the second sub-segment 142 in the same pixel region 102.

Referring to FIGS. 4 and 5, for the same pixel region 102, in the orthographic projections of the first electrode 30, the first sub-segment 141 and the second sub-segment 142 on the substrate 101, a distance D1 between at least a portion of the first electrode 30 and the first sub-segment 141 in the first direction X is greater than a distance D2 between at least the portion of the first electrode 30 and the second sub-segment 142 in the first direction X. In this way, it may be possible to increase the distance between the first electrode 30 and the first portion 11, thereby reducing the capacitance difference between the first parasitic capacitor Cpd1 and the second parasitic capacitor Cpd2, reducing the voltage (ΔV) generated by the coupling of the first electrode 30 with both the first parasitic capacitor Cpd1 and the second parasitic capacitor Cpd2, and reducing the voltage fluctuation of the first electrode 30. Thus, the change of the electric field between the first electrode 30 and the second electrode 40 is reduced, thereby improving the display quality of the display panel.

In some embodiments, referring to FIGS. 3, 7 and 8, the first electrode 30 includes a first sub-electrode 31, a second sub-electrode 32, and a third sub-electrode 33 that are arranged in a direction away from the substrate 101. The first sub-electrode 31 is electrically connected to the second electrode of the first transistor T1, the second sub-electrode 32 is electrically connected to the first sub-electrode 31, and the third sub-electrode 33 is electrically connected to the second sub-electrode 32.

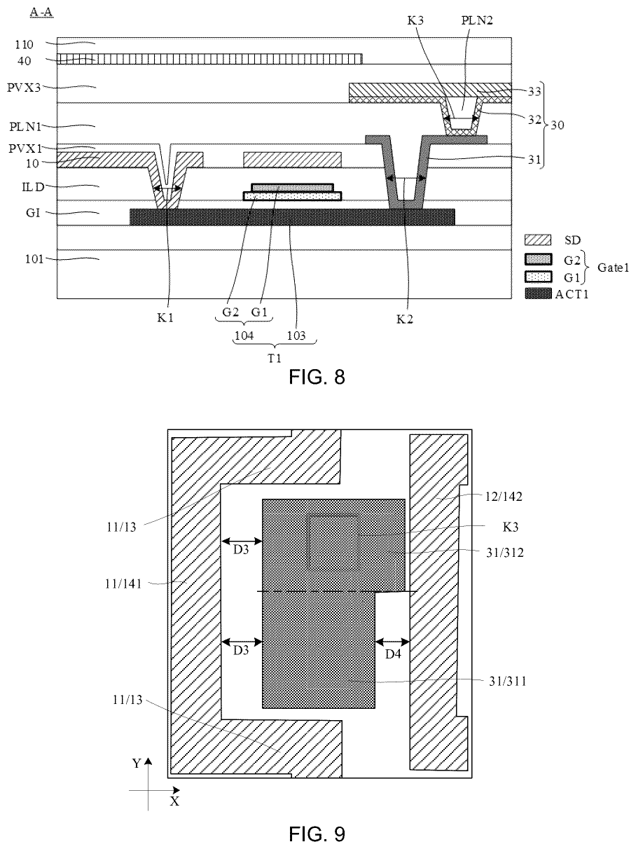

In some embodiments, referring to FIG. 8, the array substrate 100 can include a first semiconductor layer ACT1, a first insulating layer GI, a first gate conductive layer Gate1, a second insulating layer ILD, a source-drain conductive layer SD, a third insulating layer PVX1, a first planarization layer PLN1 and a second planarization layer PLN2 that are arranged in a direction away from the substrate 101 (in a direction from bottom to top in FIG. 8). The array substrate 100 further includes: first via holes K1 penetrating through the first insulating layer GI and the second insulating layer ILD, second via holes K2 penetrating through the first insulating layer GI, the second insulating layer ILD and the third insulating layer PVX1, and third via holes K3 penetrating through the first planarization layer PLN1.

A material of the first semiconductor layer ACT1 can include one or more of amorphous silicon, polysilicon, metal oxide material(s), and metal oxynitride material(s). The metal oxide material(s) include, but are not limited to: one or more of indium gallium zinc oxide (IGZO), indium gallium tin oxide (IGTO), indium tin zinc oxide (ITZO), indium gallium oxide (IGO), indium gallium zinc tin oxide (IGZTO), indium zinc oxide (IZO), zinc tin oxide (ZTO), indium-free metal oxide (In-free OS), rare earth doped oxide (Ln-OS), zinc oxide (ZnO), gallium oxide (GaO), indium oxide (InO), HfInZnO (HIZO), ZnO:F, In₂O₃:Sn, In₂O₃:Mo, Cd₂SnO₄, ZnO:Al, TiO₂:Nb, and Cd—Sn—O.

The metal oxynitride material(s) include, but are not limited to: at least one of zinc oxynitride, indium oxynitride, gallium oxynitride, tin oxynitride, cadmium oxynitride, aluminum oxynitride, germanium oxynitride, titanium oxynitride, and silicon oxynitride. The polysilicon may include low temperature polysilicon (LTPS).

The material of the first semiconductor layer ACT1 may be in an amorphous state, a partially crystalline state, a single crystal state or a polycrystalline state, and the first semiconductor layer ACT1 may be of a single layer or multi-layer structure.

The first transistor T1 includes a first semiconductor pattern 103 located in the first semiconductor layer ACT1 and a first gate pattern 104 located in the first gate conductive layer Gtae1. The first semiconductor pattern 103 can include a channel portion, and a first electrode portion and a second electrode portion located on both sides of the channel portion. An orthographic projection of the channel portion on the substrate 101 coincides with an orthographic projection of the first gate pattern 104 on the substrate 101, one of the first electrode portion and the second electrode portion is configured to form the first electrode of the first transistor T1, and the other of the first electrode portion and the second electrode portion is configured to form the second electrode of the first transistor T1. For example, as shown in FIG. 8, the first electrode portion is located on the left side of the channel portion, for forming the first electrode of the first transistor T1 and for being electrically connected to the first signal line 10; and the second electrode portion is located on the right side of the channel portion, for forming the second electrode of the first transistor T1 and for being electrically connected to the first electrode 30.

The first signal line 10 is disposed in the source-drain conductive layer SD, and the first signal line 10 passes through the first via hole K1 to be electrically connected to the first semiconductor pattern 103 (first electrode portion). At least a portion of the first sub-electrode 31 is disposed between the third insulating layer PVX1 and the first planarization layer PLN1, and a portion of the first sub-electrode 31 passes through the second via hole K2 to be electrically connected to the first semiconductor pattern 103 (the second electrode portion). An orthographic projection of the third via hole K3 on the substrate 101 is non-overlapping with an orthographic projection of the second via hole K2 on the substrate 101, so as to reduce the depth of the third via hole K3 and improve the flatness degree of the second sub-electrode 32. The third via hole K3 exposes a portion of the first sub-electrode 31, and the second sub-electrode 32 passes through the third via hole K3 to be electrically connected to the first sub-electrode 31.

The array substrate 100 further includes the second planarization layer PLN2, which is disposed on a side of the second sub-electrode 32 away from the substrate 101. The second planarization layer PLN2 covers a portion of the second sub-electrode 32 located in the third via hole K3 and exposes at least a portion of the second sub-electrode 32 located on the first planarization layer PLN1. The third sub-electrode 33 covers the second planarization layer PLN2 and at least a portion of the second sub-electrode 32, so as to be electrically connected to the second sub-electrode 32. The second planarization layer PLN2 can increase the flatness degree of the surface of the third sub-electrode 33. For example, the surface of the second planarization layer PLN2 away from the substrate 101 is flush or approximately flush with the surface of a portion, located on the first planarization layer PLN1, of the second sub-electrode 32 away from the substrate 101. In this way, the flatness degree of the surface of the third sub-electrode 33 may be greatly increased, which is beneficial to forming the storage capacitor C1 between the third sub-electrode 33 and the second electrode 40.

In some embodiments, referring to FIG. 8, the first gate conductive layer Gate1 can be of a stacked structure. For example, the first gate conductive layer Gate1 includes a first material layer G1 and a second material layer G2 that are stacked; a material of the first material layer G1 includes a transparent conductive material, and a material of the second material layer G2 includes a metal material. For example, the transparent conductive material includes indium tin oxide (ITO); and the second material layer G2 includes a single metal material layer or a metal stacked-layer. For example, the metal stacked-layer includes one of a titanium-aluminum-titanium (Ti/Al/Ti) stacked-layer, a molybdenum-aluminum (Mo/Al) stacked-layer, a molybdenum-aluminum-molybdenum (Mo/Al/Mo) stacked-layer, a molybdenum niobium-titanium (MoNb/Ti) stacked-layer, a molybdenum niobium-titanium-copper (MoNb/Ti/Cu) stacked-layer, a molybdenum niobium-copper-molybdenum titanium nickel (MoNb/Cu/MTD) stack, a molybdenum-neodymium-copper stacked-layer, a MoNb-copper-MoNb stacked-layer, and an AlNb-molybdenum-AlNd stacked-layer.

In some embodiments, referring to FIG. 8, the array substrate 100 can further include a fifth insulating layer PVX3 disposed between the third sub-electrode 33 and the second electrode 40. The fifth insulating layer PVX3 is used to isolate the third sub-electrode 33 from the second electrode 40, so as to prevent the short circuit between the third sub-electrode 33 and the second electrode 40. The array substrate 100 can further include a sixth insulating layer 110 covering the fourth electrode 40, and the sixth insulating layer 110 is used for protecting the second electrode 40.

In some embodiments of the present disclosure, as shown in FIG. 8, the first electrode 30 includes the first sub-electrode 31, the second sub-electrode 32 and the third sub-electrode 33. In this way, it may be possible to reduce the depths of the second via hole K2 and the third via hole K3, reduce the climbing difficulty of the first sub-electrode 31 on the side wall of the second via hole K2, and improve the connection reliability between the first sub-electrode 31 and the first semiconductor pattern 103. In addition, the climbing difficulty of the second sub-electrode 31 on the side wall of the third via hole K3 is reduced, and the connection reliability between the second sub-electrode 32 and the first sub-electrode 31 is improved. The second planarization layer PLN2 fills the gap between the third sub-electrode 33 and the second sub-electrode 32, which is beneficial to improving the flatness degree of the third sub-electrode 33.

A distance between an orthographic projection of at least a portion of at least one of the first sub-electrode 31, the second sub-electrode 32 and the third sub-electrode 33 on the substrate 101 and an orthographic projection of the first sub-segment 141 on the substrate 101 in the first direction X is greater than a distance between the orthographic projection of at least the portion of the at least one of the first sub-electrode 31, the second sub-electrode 32 and the third sub-electrode 33 on the substrate 101 and an orthographic projection of the second sub-segment 142 on the substrate 101 in the first direction X. In this way, capacitance of the parasitic capacitor formed between the first sub-segment 141 and the at least one of the first sub-electrode 31, the second sub-electrode 32 and the third sub-electrode 33 may be reduced, which is beneficial to reducing the capacitance difference between the first parasitic capacitor Cpd1 and the second parasitic capacitor Cpd2, and reducing the voltage (ΔV) generated by the coupling of the first electrode 30 with both the first parasitic capacitor Cpd1 and the second parasitic capacitor Cpd2. Thus, it may be possible to improve the stability of the voltage difference between the first electrode 30 and the second electrode 40, thereby improving the display quality of the display panel.

For example, in orthographic projections of the first sub-segment 141, the second sub-segment 142, the first sub-electrode 31, the second sub-electrode 32 and the third sub-electrode 33 on the substrate 101, a distance between the first sub-segment 141 and part or all of one of the first sub-electrode 31, the second sub-electrode 32 and the third sub-electrode 33 (e.g., the first sub-electrode 31, the second sub-electrode 32 or the third sub-electrode 33) is greater than a distance between the second sub-segment 142 and the part or all of the one of the first sub-electrode 31, the second sub-electrode 32 and the third sub-electrode 33; and distances between the first sub-segment 141 and the other two of the first sub-electrode 31, the second sub-electrode 32 and the third sub-electrode 33 are equal to distances between the second sub-segment 142 and the other two of the first sub-electrode 31, the second sub-electrode 32 and the third sub-electrode 33, respectively. Alternatively, part or all of two of the first sub-electrode 31, the second sub-electrode 32 and the third sub-electrode 33 (e.g., the first sub-electrode 31 and the second sub-electrode 32, or the first sub-electrode 31 and the third sub-electrode 33, or the second sub-electrode 32 and the third sub-electrode 33) can have larger distances from the first sub-segment 141 than from the second sub-segment 142, and a distance between the first sub-segment 141 and the other one of the first sub-electrode 31, the second sub-electrode 32 and the third sub-electrode 33 is equal to a distance between the second sub-segment 142 and the other one of the first sub-electrode 31, the second sub-electrode 32 and the third sub-electrode 33. Alternatively, for the first sub-electrode 31, the second sub-electrode 32, and the third sub-electrode 33, a distance between part or all of each one and the first sub-segment 141 can be greater than a distance between the part or all of the one and the second sub-segment 142.

In some embodiments, referring to FIG. 9, the first sub-electrode 31 includes a third portion 311 and a fourth portion 312. The fourth portion 312 is located on a side of the third portion 311 in the second direction Y and is connected to the third portion 311. For example, the fourth portion 312 is located on an upper side of the third portion 311. In orthographic projections of the third portion 311, the first sub-segment 141 and the second sub-segment 142 on the substrate 101, a distance D3 between the third portion 311 and the first sub-segment 141 in the first direction X is greater than a distance D4 between the third portion 311 and the second sub-segment 142 in the first direction X. An edge of the fourth portion 312 close to the first sub-segment 141 is flush with an edge of the third portion 311 close to the first sub-segment 141, and an edge of the fourth portion 312 close to the second sub-segment 142 extends out of an edge of the third portion 311. A distance between the fourth portion 312 and the first sub-segment 141 in the first direction X is also D3, and a distance between the fourth portion 312 and the second sub-segment 142 is less than D4. In this way, capacitances of two parasitic capacitors generated between the first sub-electrode 31 and both the first portion 11 and the second portion 12 may be balanced to a great extent, thereby reducing the capacitance difference between the parasitic capacitors generated between the first sub-electrode 31 and both the first portion 11 and the second portion 12, and reducing the voltage generated by the coupling of the first sub-electrode 31 with the above two parasitic capacitances. Thus, it may be possible to improve the voltage stability of the first electrode 30.

For example, orthographic projections of the fourth portion 312 and the third via hole K3 on the substrate 101 overlap, and the fourth portion 312 is configured to pass through the third via hole K3 to be connected to the first semiconductor pattern 103. In the first direction X, a size of the fourth portion 312 is greater than a size of the third portion 312, which is beneficial to reducing the difficulty of aligning the fourth portion 312 with the third via hole K3. Therefore, the fourth portion 312 may cover the third via hole K3 and pass through the third via hole K3 to be connected to the first semiconductor pattern 103, thereby improving the connection reliability between the first sub-electrode 312 and the semiconductor pattern 103.

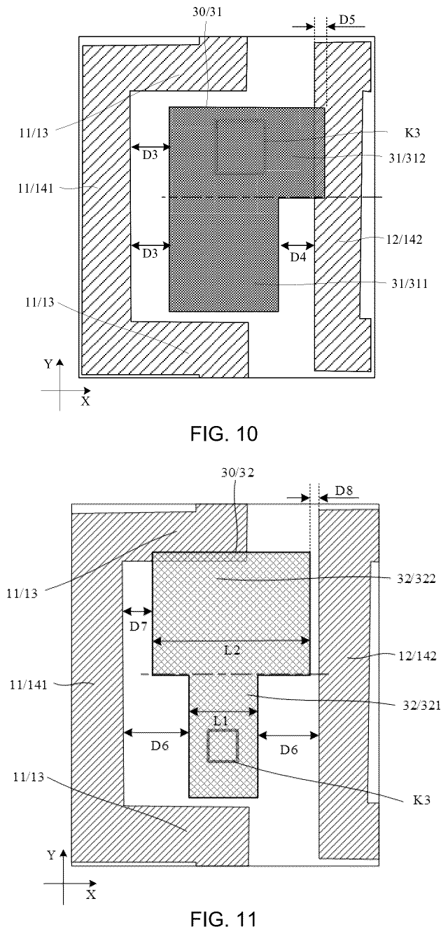

In some embodiments, referring to FIG. 10, an orthographic projection of the fourth portion 312 on the substrate 101 at least partially overlaps with an orthographic projection of the second sub-segment 142 on the substrate 101. Thus, it may be possible to further increase the magnitude of the capacitance of the parasitic capacitor formed between the fourth portion 312 and the second sub-segment 142, thereby further balancing capacitances of the two parasitic capacitors between the first sub-electrode 31 and both the first portion 11 and the second portion 12 (the second sub-segment 142), reducing the capacitance difference between the two parasitic capacitors formed between the first sub-electrode 31 and both the first portion 11 and the second portion 12, and reducing the voltage generated by the coupling of the first sub-electrode 31 with the above two parasitic capacitances. Thus, it may be possible to reduce the voltage fluctuation of the first electrode 30, thereby improving the voltage stability of the first electrode 30.

In some embodiments, referring to FIGS. 9 and 10, the distance D3 between the orthographic projections of the first sub-electrode 31 and the first sub-segment 141 on the substrate 101 in the first direction X is in a range of 0.5 μm to 1.5 μm. In this way, it may be possible to increase the distance between the first sub-electrode 31 and the first sub-segment 141, thereby reducing the magnitude of the capacitance of the parasitic capacitor generated between the first sub-electrode 31 and the first sub-segment 141. For example, a value of D3 ranges from 0.5 μm to 0.8 μm. For example, the value of D3 is 0.5 μm, 0.6 μm, 0.7 μm or 0.8 μm. Alternatively, the value of D3 ranges from 0.8 μm to 1.2 μm. For example, the value of D3 is 0.8 μm, 0.95 μm, 1 μm or 1.2 μm. Alternatively, the value of D3 ranges from 1.2 μm to 1.5 μm. For example, the value of D3 is 1.2 μm, 1.3 μm, 1.4 μm or 1.5 μm. Of course, the value of D3 is not limited to these, and other values will not be listed in the embodiments of the present disclosure one by one.

The distance D4 between the orthographic projections of the third portion 311 and the second sub-segment 142 on the substrate 101 in the first direction X is in a range of 0.2 μm to 1 μm. In this way, it may be possible to reduce the distance between the third portion 311 and the second sub-segment 142, thereby increasing the magnitude of capacitance of the parasitic capacitor generated between the third portion 311 and the second sub-segment 142.

For example, a value of D4 ranges from 0.2 μm to 0.4 μm. For example, the value of D4 is 0.2 μm, 0.3 μm, 0.35 μm or 0.4 μm. Alternatively, the value of D4 ranges from 0.4 μm to 0.7 μm. For example, the value of D4 is 0.4 μm, 0.55 μm, 0.6 μm or 0.7 μm. Alternatively, the value of D4 ranges from 0.7 μm to 1 μm. For example, the value of D4 is 0.7 μm, 0.8 μm, 0.85 μm or 1 μm. Of course, the value of D4 is not limited to these, and other values will not be listed in the embodiments of the present disclosure one by one.

A dimension D5 of a portion, whose orthographic projection on the substrate 101 overlaps with the orthographic projection of the second sub-segment 142 on the substrate 101, of the fourth portion 312 in the first direction X is in a range of 0.1 μm to 1 μm. In this way, it may be possible to increase the facing area of the fourth portion 312 and the second sub-segment 142, thereby increasing the parasitic capacitance between the fourth portion 312 and the second sub-segment 142, and balancing capacitances of the two parasitic capacitors generated between the first sub-electrode 31 and both the first portion 11 and the second portion 12. Thus, the capacitance difference between the parasitic capacitors generated between the first sub-electrode 31 and both the first portion 11 and the second portion 12 is reduced, and the voltage generated by the coupling of the first sub-electrode 31 with the above two parasitic capacitances is reduced, thereby improving the voltage stability of the first electrode 30.

For example, a value of D5 ranges from 0.1 μm to 0.4 μm. For example, the value of D5 is 0.1 μm, 0.2 μm, 0.35 μm or 0.4 μm. Alternatively, the value of D5 ranges from 0.4 μm to 0.7 μm. For example, the value of D5 is 0.4 μm, 0.5 μm, 0.65 μm or 0.7 μm. Alternatively, the value of D5 ranges from 0.7 μm to 1 μm. For example, the value of D5 is 0.7 μm, 0.85 μm, 0.9 μm or 1 μm. Of course, the value of D5 is not limited to these, and other values will not be listed in the embodiments of the present disclosure one by one.

It should be noted that, for the fourth portion 312, in addition to forming the parasitic capacitor with the first sub-segment 141 of the first portion 11, it can also form the parasitic capacitor with the first extension segment 13 of the first portion 11. By increasing the magnitude of the parasitic capacitance between the fourth portion 312 and the second sub-segment 142 or reducing the magnitude of the parasitic capacitance between the fourth portion 312 and the first sub-segment 141, it may be possible to reduce the capacitance difference between the two parasitic capacitors formed between the fourth portion 312 and both the first portion 11 and the second portion 12.

In an example, the distance D3 between the orthographic projections of the first sub-electrode 31 and the first sub-segment 141 on the substrate 101 in the first direction X is 0.95 μm, the distance D4 between the orthographic projections of the third portion 311 and the second sub-segment 142 on the substrate 101 in the first direction X is 0.55 μm, and the dimension D5, in the first direction X, of the portion of the fourth portion 312 whose orthographic projection on the substrate 101 overlaps with the orthographic projection of the second sub-segment 142 on the substrate 101 is 0.25 μm. In this way, the capacitance difference between the two parasitic capacitors formed between the first sub-electrode 31 and both the first portion 11 and the second portion 12 may be greatly reduced. For example, the capacitances of the two parasitic capacitors formed between the first sub-electrode 31 and both the first portion 11 and the second portion 12 may be equal.

In some embodiments, referring to FIG. 11, the second sub-electrode 32 includes a fifth portion 321 and a sixth portion 322. The sixth portion 322 is located on a side of the fifth portion 321 in the second direction Y, and is connected to the fifth portion 321. For example, the sixth portion 322 is located on an upper side of the fifth portion 321.

As shown in FIG. 11, a distance D7 between an orthographic projection of the sixth portion 322 on the substrate 101 and the orthographic projection of the first sub-segment 141 on the substrate 101 in the first direction X is greater than a distance D8 between the orthographic projection of the sixth portion 322 on the substrate 101 and the orthographic projection of the second sub-segment 142 on the substrate 101 in the first direction X, i.e., D7>D8. In this way, capacitances of the two parasitic capacitors generated between the second sub-electrode 32 and both the first portion 11 and the second portion 12 may be balanced to a great extent, the capacitance difference between the two parasitic capacitors generated between the second sub-electrode 32 and both the first portion 11 and the second portion 12 may be reduced, and the voltage fluctuation generated by the coupling of the second sub-electrode 32 with the above two parasitic capacitances may be reduced. Thus, it may be possible to improve the stability of the first electrode 30, thereby improving the display quality of the display panel.

With continued reference to FIG. 11, in orthographic projections of the fifth portion 321, the first sub-segment 141 and the second sub-segment 142 on the substrate 101, a distance D6 between the fifth portion 321 and the first sub-segment 141 in the first direction X is equal to a distance D6 between the fifth portion 321 and the second sub-segment 142 in the first direction X. That is, the fifth portion 321 of the second sub-electrode 32 is located in the middle of the region between the first sub-segment 141 and the second sub-segment 142.

In some embodiments, an orthographic projection of the fifth portion 321 on the substrate 101 overlaps with an orthographic projection of the third via hole K3 on the substrate 101, and the fifth portion 321 is electrically connected to the first sub-electrode 31 through the third via hole K3. That is, the fifth portion 321 is configured to be electrically connected to the first sub-electrode 31. The sixth portion 322 is in direct contact with the third sub-electrode 33, and the sixth portion 322 is configured to be electrically connected to the third sub-electrode 33.

Two ends of the sixth portion 322 in the first direction X extend out of the edges of the fifth portion 321, respectively. That is, a dimension L1 of the fifth portion 321 in the first direction X is less than a dimension L2 of the sixth portion 322 in the first direction X, i.e., L1<L2. That is to say, the distance D6 between the fifth portion 321 and the first sub-segment 141 (or the second sub-segment 142) in the first direction X is greater than a distance D7 between orthographic projections of the sixth portion 322 and the first sub-segment 141 on the substrate 101 in the first direction X, and is greater than a distance D8 between orthographic projections of the sixth portion 322 and the second sub-segment 142 on the substrate 101 in the first direction X. That is, D6>D7, and D6>D8.

Based on this, the distance D6 between the fifth portion 321 and the first sub-segment 141 as well as between the fifth portion 321 and the second sub-segment 142 in the first direction X may be greatly increased, the capacitances of the two parasitic capacitors formed between the fifth portion 321 and both the first sub-segment 141 and the second sub-segment 142 may be reduced, and magnitudes of the capacitances of the two parasitic capacitors formed between the second sub-electrode 32 and both the first portion 11 and the second portion 12 may be reduced. Thus, the capacitance difference between the two parasitic capacitors formed between the second sub-electrode 31 and both the first portion 11 and the second portion 12 may be reduced, and the voltage generated by the coupling of the second sub-electrode 32 with the above two parasitic capacitors may be reduced. In addition, it may be possible to increase the area of the sixth portion 322; and the sixth portion 322 is configured to be in contact with the third sub-electrode 33, which is beneficial to increasing the contact area between the sixth portion 322 and the third sub-electrode 33, thereby reducing the contact resistance between the sixth portion 322 and the third sub-electrode 33.

In some embodiments, referring to FIG. 11, the distance D6 between the orthographic projection of the fifth portion 321 on the substrate 101 and the orthographic projection of the first sub-segment 141 on the substrate 101 in the first direction X, as well as between the orthographic projection of the fifth portion 321 on the substrate 101 and the orthographic projection of the second sub-segment 142 on the substrate 101 in the first direction X is in a range of 1 μm to 2 μm. In this way, the magnitudes of the capacitances of the two parasitic capacitors formed between the fifth portion 321 and both the first sub-segment 141 and the second sub-segment 142 may be greatly reduced.

For example, a value of D6 ranges from 1 μm to 1.3 μm. For example, the value of D6 is 1 μm, 1.1 μm, 1.25 μm or 1.3 μm. Alternatively, the value of D6 ranges from 1.3 μm to 1.7 μm. For example, the value of D6 is 1.3 μm, 1.4 μm, 1.55 μm or 1.7 μm. Alternatively, the value of D6 ranges from 1.7 μm to 2 μm. For example, the value of D6 is 1.7 μm, 1.85 μm, 1.9 μm or 2 μm. Of course, the value of D6 is not limited to these, and other values will not be listed in the embodiments of the present disclosure one by one.

With continued reference to FIG. 11, the distance D7 between the orthographic projections of the sixth portion 322 and the first sub-segment 141 on the substrate 101 in the first direction X is in a range of 0.2 μm to 1 μm. It may be possible to reduce the magnitude of the capacitance of the parasitic capacitor formed between the sixth portion 322 and the first sub-segment 141, and balance the capacitance difference between the two parasitic capacitors formed between the sixth portion 322 and both the first portion 11 and the second portion 12.

For example, a value of D7 ranges from 0.2 μm to 0.5 μm. For example, the value of D7 is 0.2 μm, 0.35 μm, 0.4 μm or 0.5 μm. Alternatively, the value of D7 ranges from 0.5 μm to 0.8 μm. For example, the value of D7 is 0.5 μm, 0.55 μm, 0.6 μm or 0.8 μm. Alternatively, the value of D7 ranges from 0.8 μm to 1 μm. For example, the value of D7 is 0.8 μm, 0.85 μm, 0.9 μm or 1 μm. Of course, the value of D7 is not limited to these, and other values will not be listed in the embodiments of the present disclosure one by one.

The distance D8 between the orthographic projections of the sixth portion 322 and the second sub-segment 142 on the substrate 101 in the first direction X is in a range of 0 to 1 μm. In this way, it may be possible to increase the magnitude of the capacitance of the parasitic capacitor formed between the sixth portion 322 and the second sub-segment 142, and balance the capacitance difference between the two parasitic capacitors formed between the sixth portion 322 and both the first portion 11 and the second portion 12.

For example, a value of D8 ranges from 0 μm to 0.3 μm. For example, the value of D8 is 0 μm, 0.15 μm, 0.2 μm or 0.3 μm. Alternatively, the value of D8 ranges from 0.3 μm to 0.7 μm. For example, the value of D8 is 0.3 μm, 0.55 μm, 0.6 μm or 0.7 μm. Alternatively, the value of D8 ranges from 0.7 μm to 1 μm. For example, the value of D8 is 0.7 μm, 0.85 μm, 0.9 μm or 1 μm. Of course, the value of D8 is not limited to these, and other values will not be listed in the embodiments of the present disclosure one by one.

It should be noted that, for the sixth portion 322, in addition to forming the parasitic capacitor with the first sub-segment 141 of the first portion 11, it can also form the parasitic capacitor with the first extension segment 13 of the first portion 11. By increasing the magnitude of the capacitance of the parasitic capacitor between the sixth portion 322 and the second sub-segment 142 or reducing the magnitude of the capacitance of the parasitic capacitor between the sixth portion 322 and the first sub-segment 141, it may be possible to reduce the capacitance difference between the two parasitic capacitors formed between the sixth portion 322 and both the first portion 11 and the second portion 12.

In an example, the distance D6 between the orthographic projection of the fifth portion 321 on the substrate 101 and the orthographic projection of the first sub-segment 141 on the substrate 101 in the first direction X, as well as between the orthographic projection of the fifth portion 321 on the substrate 101 and the orthographic projection of the second sub-segment 142 on the substrate 101 in the first direction X is 1.45 μm; the distance D7 between the orthographic projections of the sixth portion 322 and the first sub-segment 141 on the substrate 101 in the first direction X is 0.55 μm; and the distance D8 between the orthographic projections of the sixth portion 322 and the second sub-segment 142 on the substrate 101 in the first direction X is 0.15 μm. In this way, the capacitance difference between the two parasitic capacitors formed between the second sub-electrode 32 and both the first portion 11 and the second portion 12 may be greatly reduced. For example, the capacitances of the two parasitic capacitors formed between the second sub-electrode 32 and both the first portion 11 and the second portion 12 may be equal.

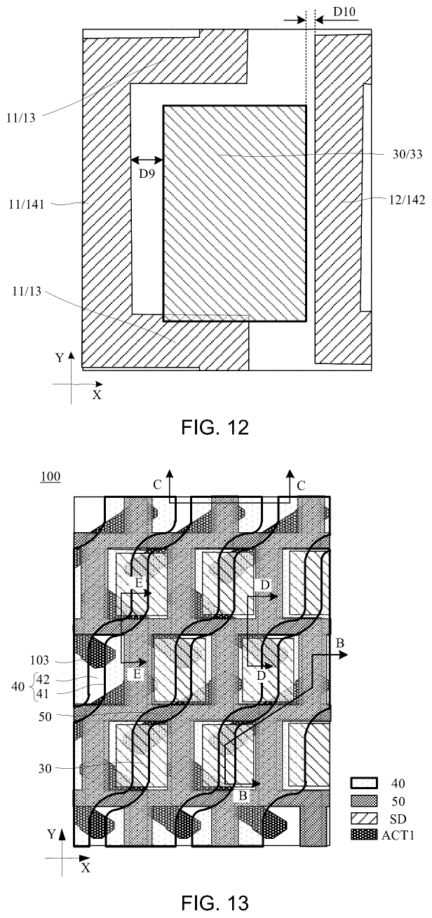

In some embodiments, referring to FIG. 12, in orthographic projections of the third sub-electrode 33, the first sub-segment 141 and the second sub-segment 142 on the substrate 101, borders, close to each other, of the third sub-electrode 33 and the first sub-segment 141 are approximately parallel, and borders, close to each other, of the third sub-electrode 33 and the second sub-segment 142 are approximately parallel. That is, distances between different portions of the third sub-electrode 33 in the second direction Y and the first sub-segment 141 are equal, and distances between different portions of the third sub-electrode 33 in the second direction Y and the second sub-segment 142 are equal. In this way, the third sub-electrode 33 may be formed into a regular shape; and the shape of the third sub-electrode 33 is similar to that of the pixel region 102, which is beneficial to forming the pixel region 102 with a regular shape.

Referring to FIG. 12, a distance D9 between the third sub-electrode 33 and the first sub-segment 141 in the first direction X is greater than a distance D10 between the third sub-electrode 33 and the second sub-segment 142 in the first direction X. In this way, it may be possible to balance the magnitudes of the capacitances of the two parasitic capacitors formed between the third sub-electrode 33 and both the first portion 11 and the second portion 12 (the second sub-segment 142), thereby reducing the capacitance difference between the two parasitic capacitors formed between the third sub-electrode 31 and both the first portion 11 and the second portion 12, and reducing the voltage fluctuation generated by the coupling of the third sub-electrode 33 with the above two parasitic capacitors. Thus, it may be possible to improve the stability of the voltage difference between the first electrode 30 and the second electrode 40, thereby improving the display quality of the display panel.

In some embodiments, referring to FIG. 12, the distance D9 between the orthographic projections of the third sub-electrode 33 and the first sub-segment 141 on the substrate 101 in the first direction X is in a range of 0.2 μm to 1 μm. Thus, it may be possible to increase the distance between the third sub-electrode 33 and the first sub-segment 141, thereby reducing the magnitude of the capacitance of the parasitic capacitor formed between the third sub-electrode 33 and the first sub-segment 141, and balancing the capacitance difference between the two parasitic capacitors formed between the third sub-electrode 33 and both the first portion 11 and the second portion 12.

For example, a value of D9 ranges from 0.2 μm to 0.5 μm. For example, the value of D9 is 0.2 μm, 0.35 μm, 0.4 μm or 0.5 μm. Alternatively, the value of D9 ranges from 0.5 μm to 0.8 μm. For example, the value of D9 is 0.5 μm, 0.55 μm, 0.7 μm or 0.8 μm. Alternatively, the value of D9 ranges from 0.8 μm to 1 μm. For example, the value of D9 is 0.8 μm, 0.9 μm, 0.95 μm or 1 μm. Of course, the value of D9 is not limited to these, and other values will not be listed in the embodiments of the present disclosure one by one.

The distance D10 between the orthographic projections of the third sub-electrode 33 and the second sub-segment 142 on the substrate 101 in the first direction X is in a range of 0 to 1 μm. It may be possible to reduce the distance between the third sub-electrode 33 and the second sub-segment 142, thereby increasing the magnitude of the capacitance of the parasitic capacitor formed between the third sub-electrode 33 and the second sub-segment 142, and balancing the capacitance difference between the two parasitic capacitors formed between the third sub-electrode 33 and both the first portion 11 and the second portion 12.

For example, a value of D10 ranges from 0 μm to 0.4 μm. For example, the value of D10 is 0 μm, 0.15 μm, 0.2 μm or 0.4 μm. Alternatively, the value of D10 ranges from 0.4 μm to 0.7 μm. For example, the value of D10 is 0.4 μm, 0.55 μm, 0.6 μm or 0.7 μm. Alternatively, the value of D10 ranges from 0.7 μm to 1 μm. For example, the value of D10 is 0.7 μm, 0.85 μm, 0.9 μm or 1 μm. Of course, the value of D10 is not limited to these, and other values will not be listed in the embodiments of the present disclosure one by one.

It should be noted that, for the third sub-electrode 33, in addition to forming the parasitic capacitor with the first sub-segment 141 of the first portion 11, it can also form the parasitic capacitor with the first extension segment 13 of the first portion 11. By increasing the magnitude of the capacitance of the parasitic capacitor between the third sub-electrode 33 and the second sub-segment 142, or reducing the magnitude of the capacitance of the parasitic capacitor between the third sub-electrode 33 and the first sub-segment 141, it may be possible to reduce the capacitance difference between the two parasitic capacitors formed between the third sub-electrode 33 and both the first portion 11 and the second portion 12.

In an example, the distance D9 between the orthographic projections of the third sub-electrode 33 and the first sub-segment 141 on the substrate 101 in the first direction X is 0.55 μm, and the distance D10 between the orthographic projections of the third sub-electrode 33 and the second sub-segment 142 on the substrate 101 in the first direction X is 0.15 μm. In this way, the capacitance difference between the two parasitic capacitors formed between the third sub-electrode 33 and both the first portion 11 and the second portion 12 may be greatly reduced. For example, the capacitances of the two parasitic capacitors formed between the third sub-electrode 33 and both the first portion 11 and the second portion 12 may be equal.

It should be noted that, the above-mentioned multiple embodiments, regarding the structures of the first sub-electrode 31, the second sub-electrode 32 and the third sub-electrode 33, and regarding the relative positions of the first sub-electrode 31, the second sub-electrode 32 and the third sub-electrode 33 to the first portion 11 and the second portion 12, can be implemented individually or in combination in any suitable manner, as long as the same technical ideas are adopted. For example, one or two of the first sub-electrode 31, the second sub-electrode 32 and the third sub-electrode 33 can be implemented in the manner described in the above embodiments, and the remaining two or one can be implemented in another suitable manner. For example, for the structures of the first sub-electrode 31 and the second sub-electrode 32 and the relative positions of the two to the first portion 11 and the second portion 12, the embodiments as described above are adopted; and the orthographic projection of the third sub-electrode 33 on the substrate 101 can be located in the middle of the region between the orthographic projections of the first sub-segment 141 and the second sub-segment 142 on the substrate 101. Of course, the embodiments of the present disclosure are not limited to this, and the above-mentioned multiple embodiments can be arbitrarily combined, which will not be repeated here one by one.

In some embodiments, referring to FIGS. 13, 14 and 15, the array substrate 100 further includes a first auxiliary layer 50 disposed between the layer (i.e., the source-drain conductive layer SD) where the first signal lines 10 are located and the layer where the first electrodes 30 are located. In other words, during the manufacturing process of the array substrate 100, the first signal lines 10 are first formed, then the first auxiliary layer 50 is formed, and after that, the first electrodes 30 are formed. In this case, in a direction perpendicular to the substrate 101, the first auxiliary layer 50 is not necessarily located between the first signal line 10 and the first electrode 30. For example, at a position where the first electrode 30 is connected to the first transistor T1, a portion of the first electrode 30 is closer to the substrate 101 than the first auxiliary layer 50.

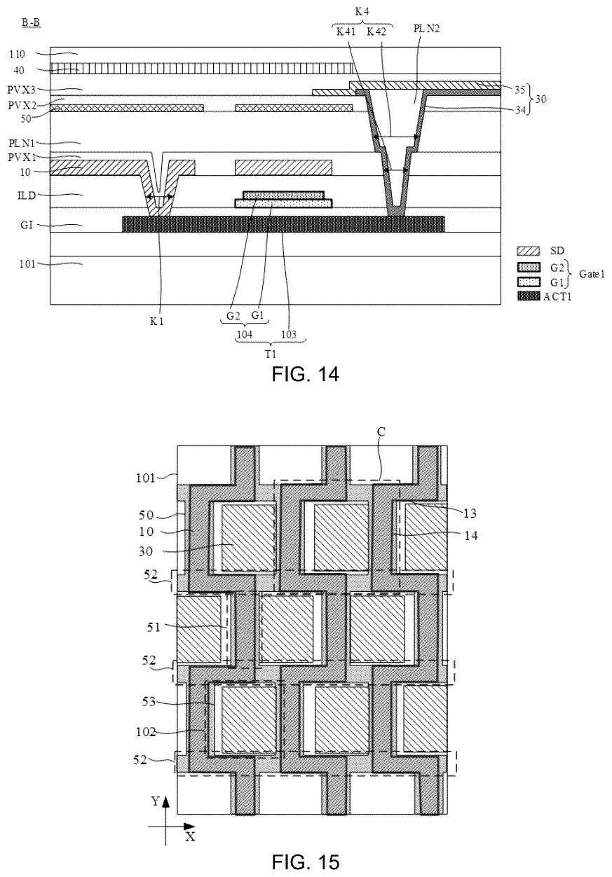

Referring to FIGS. 14 and 15, in orthographic projections of the first auxiliary layer 50, the first signal line 10 and the first electrode 30 on the substrate 101, the first auxiliary layer 50 at least partially overlaps with the first signal line 10, and/or the first auxiliary layer 50 at least partially overlaps with the first electrode 30. In this way, the first auxiliary layer 50 may shield at least part of the first signal line 10, and/or shield at least part of the first electrode 30, thereby reducing the magnitude of the capacitance of the parasitic capacitor formed between the first signal line 10 and the first electrode 30, and reducing the magnitudes of the capacitances of the two parasitic capacitors (the first parasitic capacitor Cpd1 and the second parasitic capacitor Cpd2) generated between the first electrode 30 and both the first portion 11 and the second portion 12. Thus, the capacitance difference between the above two parasitic capacitors is reduced, which is beneficial to reducing the voltage fluctuation of the first electrode 30, thereby improving the voltage stability of the first electrode 30, and improving the display quality of the display panel.

For example, in the orthographic projections of the first auxiliary layer 50, the first signal lines 10 and the first electrodes 30 on the substrate 101, the first auxiliary layer 50 at least partially overlaps with the first signal line 10, and the first auxiliary layer 50 is non-overlapping with the first electrode 30. Alternatively, the first auxiliary layer 50 is non-overlapping with the first signal line 10, and the first auxiliary layer 50 at least partially overlaps with the first electrode 30. Alternatively, the first auxiliary layer 50 at least partially overlaps with the first signal line 10, and the first auxiliary layer 50 at least partially overlaps with the first electrode 30.

In some embodiments, referring to FIGS. 14 and 15, the orthographic projection of the first auxiliary layer 50 on the substrate 101 covers the orthographic projection of the first signal line 10 on the substrate 101. In this way, the magnitude of the capacitance of the parasitic capacitor generated between the first signal line 10 and the first electrode 30 may be greatly reduced, thereby reducing the capacitance difference between the two parasitic capacitors (the first parasitic capacitor Cpd1 and the second parasitic capacitor Cpd2) generated between the first electrode 30 and two first signal lines 10 adjacent to the first electrode 30. Thus, it may be possible to reduce the voltage fluctuation of the first electrode 30, thereby improving the voltage stability of the first electrode 30, and improving the display quality of the display panel. The orthographic projection of the first auxiliary layer 50 on the substrate 101 is non-overlapping with at least a portion of the orthographic projection of the first electrode 30 on the substrate 101. In this way, an area of a portion of the first auxiliary layer 50 in the pixel region 102 may be reduced, and the shielding of the light in the pixel region 102 by the first auxiliary layer 50 may be reduced, which is beneficial to improving the light transmittance of the array substrate. Thus, the light extraction efficiency of the display panel may be improved.

For example, referring to FIG. 15, the orthographic projection of the first auxiliary layer 50 on the substrate 101 is non-overlapping with the orthographic projection of the first electrode 30 on the substrate 101. In this way, the area of the first auxiliary layer 50 in the pixel region 102 may be greatly reduced, and the shielding of the light in the pixel region 102 by the first auxiliary layer 50 may be greatly reduced, thereby improving the light extraction rate of the array substrate.

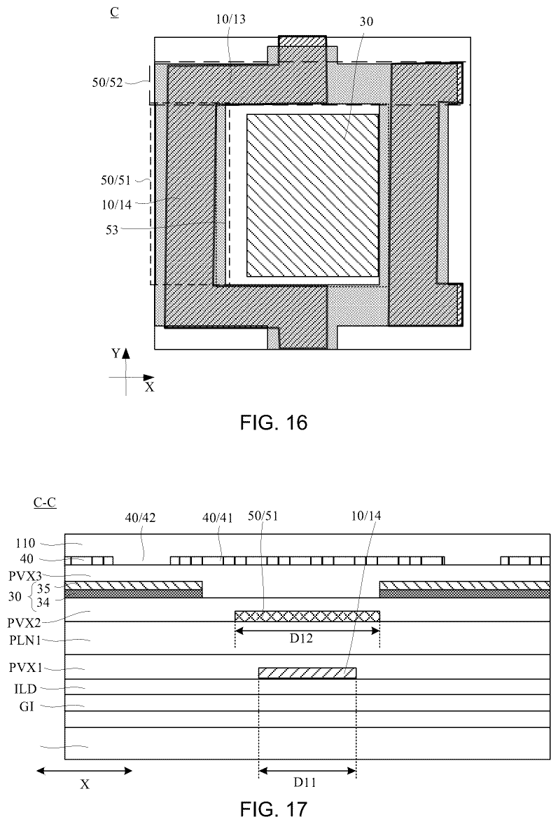

In some embodiments, referring to FIGS. 15 and 16, the first signal line 10 includes the plurality of first extension segments 13 and the plurality of second extension segments 14 that are alternately connected; the first auxiliary layer 50 is of a grid structure, and includes a plurality of first sub-portions 51, a plurality of second sub-portions 52, and a plurality of grid holes 53.

The plurality of first sub-portions 51 extend in the second direction Y, and an orthographic projection of a single first sub-portion 51 on the substrate 101 covers an orthographic projection of a single second extension segment 14 on the substrate 101. The plurality of second sub-portions 52 extend in the first direction X, and an orthographic projection of a single second sub-portion 52 on the substrate 101 covers orthographic projections, on the substrate 101, of multiple first extension segments 13 that are arranged in the first direction X. For example, the second sub-portion 52 can extend continuously in the first direction X, and the second sub-portion 52 can cover a gap between two adjacent first extension segments 13 in the first direction X. In this way, the orthographic projection of the first auxiliary layer 50 on the substrate 101 may completely cover the orthographic projections of the plurality of first signal lines 10 on the substrate 101, thereby avoiding the influence of the first signal lines 10 on the first electrodes 30 to a great extent.

A grid hole 53 corresponds to a pixel region 102, and the grid hole 53 exposes at least a portion of the pixel region 102 corresponding to the grid hole 53. The grid hole 53 may reduce the shielding of the pixel region 102 by the first auxiliary layer 50, thereby reducing the influence of the first auxiliary layer 50 on the light extraction efficiency of the pixel region 102.

In some embodiments, as shown in FIG. 14, the array substrate 100 further includes a first semiconductor layer ACT1, a first insulating layer GI, a first gate conductive layer Gate1, a second insulating layer ILD, a source-drain conductive layer SD, a third insulating layer PVX1 and a first planarization layer PLN1 that are arranged in a direction away from the substrate 101, and first via holes K1 passing through the first insulating layer GI and the second insulating layer ILD. The first signal line 10 passes through the first via hole K1 to be electrically connected to a first semiconductor pattern 103. The first transistor T1 includes the first semiconductor pattern 103 located in the first semiconductor layer ACT1 and a first gate pattern 104 located in the first gate conductive layer Gtae1. The first signal line 10 is arranged in the source-drain conductive layer SD.

Different from the above-mentioned embodiment shown in FIG. 8, in this embodiment, referring to FIG. 14, in a case where the array substrate 100 is provided with the first auxiliary layer 50, the first electrode 30 can have two layers of sub-electrodes; and the first electrode 30 includes a fourth sub-electrode 34 and a fifth sub-electrode 35 arranged in sequence in a direction away from the substrate 101, the fourth sub-electrode 34 is electrically connected to the second electrode of the first transistor T1, and the fifth sub-electrode 35 is electrically connected to the fourth sub-electrode 34. In this way, the number of conductive layers included in the array substrate 100 remains unchanged, which is beneficial to reducing the thickness and manufacturing cost of the array substrate 100.

As shown in FIG. 14, the array substrate 100 further includes a fourth insulating layer PVX2, a second planarization layer PLN2, and fourth via holes K4 that penetrates through the first insulating layer GI, the second insulating layer ILD, the third insulating layer PVX1, the first planarization layer PLN1 and the fourth insulating layer PVX2; the fourth sub-electrode 34 is disposed on a side of the fourth insulating layer PVX2 away from the substrate 101, and the fourth sub-electrode 34 passes through the fourth via hole K4 to be electrically connected to the first semiconductor pattern 103.

The first auxiliary layer 50 is disposed between the first planarization layer PLN1 and the fourth insulating layer PVX2. The second planarization layer PLN2 is disposed on a side of the fourth sub-electrode 34 away from the substrate 101, covers a portion of the fourth sub-electrode 34 in the fourth via hole K4, and exposes at least a portion of the fourth sub-electrode 34 on the fourth insulating layer PVX2. For example, a surface of the second planarization layer PLN2 away from the substrate 101 is substantially flush with a surface of a portion, located on the fourth insulating layer PVX2, of the fourth sub-electrode 34 away from the substrate 101, which is beneficial to improving the flatness degree of the fifth sub-electrode 35. The fifth sub-electrode 35 covers the second planarization layer PLN2 and at least a portion of the fourth sub-electrode 34 to be electrically connected to the fourth sub-electrode 34. The second planarization layer PLN2 can increase the flatness degree of the surface of the fifth sub-electrode 35, which is beneficial to forming the storage capacitor C1 between the fifth sub-electrode 35 and the second electrode 40. For example, the fifth sub-electrode 35 covers the surface of the fourth sub-electrode 34 away from the substrate 101.

In some embodiments, referring to FIG. 14, the array substrate 100 can further include a fifth insulating layer PVX3 disposed between the fifth sub-electrode 34 and the second electrode 40. The fifth insulating layer PVX3 is used to isolate the fifth sub-electrode 35 from the second electrode 40 to prevent a short circuit between the fifth sub-electrode 35 and the second electrode 40. The array substrate 100 can further include a sixth insulating layer 110 covering the second electrode 40, and the sixth insulating layer 110 is used for protecting the second electrode 40.

Some embodiments of the present disclosure further provide a manufacturing method of the display substrate 100 shown in FIGS. 13 and 14. The manufacturing method of the array substrate includes as follows. The first semiconductor layer ACT1, the first insulating layer GI, the first gate conductive layer Gate1, and the second insulating layer ILD are sequentially formed on the substrate 101. Then, first via holes K1 penetrating through the first insulating layer GI and the second insulating layer ILD are formed, and a first via hole K1 exposes a portion of the first semiconductor layer ACT1. Then, the source-drain conductive layer SD, the third insulating layer PVX1, the first planarization layer PLN1, the first auxiliary layer 50 and the fourth insulating layer PVX2 are sequentially formed. After that, first sub-holes K41 penetrating through the fourth insulating layer PVX2 and the first planarization layer PLN1 are formed through a photolithography process (a mask), and then second sub-holes K42 penetrating through the third insulating layer PVX1, the second insulating layer ILD and the first insulating layer GI are formed by using the first planarization layer PLN1 as a mask and by etching. A second sub-hole K42 is communicated with a first sub-hole K41 to form the fourth via hole K4. Then, the fourth sub-electrodes 34, the second planarization layer PLN2, the fifth sub-electrodes 35, the fifth insulating layer PVX3, the second electrode 40 and the sixth insulating layer 110 are sequentially formed. In the above manufacturing method, although the formation of the fourth via hole K4 undergoes two etching processes, the mask for forming the second sub-hole K42 may be omitted, which is beneficial to simplifying the manufacturing process of the array substrate and reducing the manufacturing cost of the array substrate 100.

In some embodiments, referring to FIG. 14, the fourth via hole K4 can include the first sub-hole K41 penetrating through the first planarization layer PLN1 and the fourth insulating layer PVX2, and the second sub-hole K42 penetrating through the first insulating layer GI, the second insulating layer ILD and the third insulating layer PVX1. A step structure can be formed at the connection between the first sub-hole K41 and the second sub-hole K42. In this way, the climbing difficulty of the fourth sub-electrode 34 on the side wall of the fourth via hole K4 may be reduced, which is conducive to improving the connectivity of the fourth sub-electrode 34 in the fourth via hole K4.

In some embodiments, referring to FIGS. 13 and 17, the array substrate 100 further includes the second electrode 40 disposed on a side of the first electrode 30 away from the substrate 101. The first auxiliary layer 50 and the second electrode 40 transmit the same voltage signal. That is, the first auxiliary layer 50 transmits a constant voltage signal. In this way, even if parasitic capacitance is generated between the first auxiliary layer 50 and the first signal line 10, the parasitic capacitance will not affect the voltage of the first auxiliary layer 50, which is conducive to maintaining the voltage stability of the first auxiliary layer 50. Parasitic capacitance can also be formed between the first auxiliary layer 50 and the first electrode 30. Since the voltage stability of the first auxiliary layer 50 is relatively high (compared to the first signal line 10), the parasitic capacitance will not affect the voltage of the first electrode 30, or the influence of the parasitic capacitance on the first electrode 30 is slight and can be ignored.

In some embodiments, referring to FIG. 17, the orthographic projection of the first auxiliary layer 50 on the substrate 101 at least partially overlaps with the orthographic projection of the second electrode 40 on the substrate 101. In this way, it may be possible to reduce the influence of the first auxiliary layer 50 on the electric field generated between the first electrode 30 and the second electrode 40, thereby reducing the influence of the first auxiliary layer 50 on the shape and position of the second electrode 40.

In some embodiments, referring to FIGS. 13 and 17, in orthographic projections of the second electrode 40 and the first sub-portion 51 on the substrate 101, the second electrode 40 covers the first sub-portion 51, and there is an interval between a border of the second electrode 40 and a border of the first sub-portion 51. In this way, the influence of the first sub-portion 51 on the electric field formed between the first electrode 30 and the second electrode 40 may be greatly reduced.

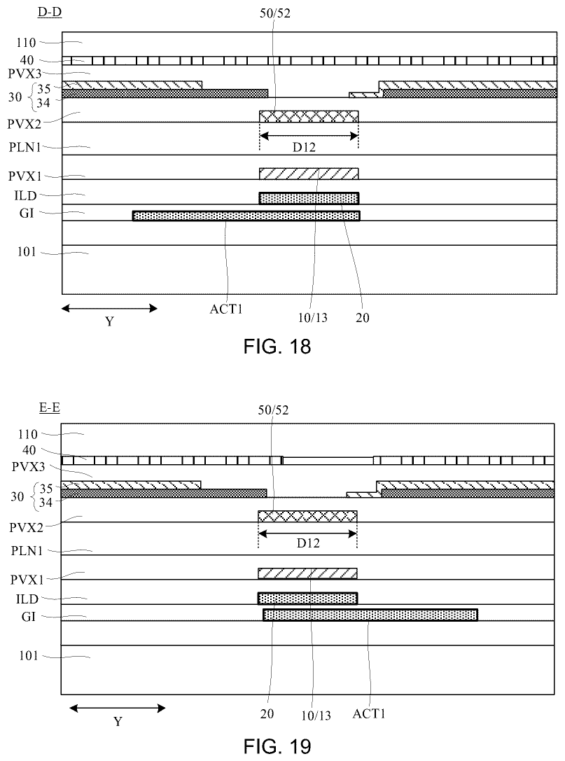

Referring to FIGS. 13, 18 and 19, the orthographic projection of the second electrode 40 on the substrate 101 partially overlaps with the orthographic projection of the second sub-portion 52 on the substrate 101. In the orthographic projections of the second electrode 40 and the second sub-portion 52 on the substrate 101, an overlapping portion of the second electrode 40 with the second sub-portion 52 (as shown in FIGS. 13 and 18) helps to maintain the continuity of the second electrode 40 in the second direction Y, and helps to connect the second electrode 40 to a corresponding signal line in a peripheral region; and a non-overlapping portion of the second electrode 40 with the second sub-portion 52 (as shown in FIGS. 13 and 19) helps to form an opening (slit) 42 in the second electrode 40, so as to pattern the second electrode 40.

For example, as shown in FIG. 13, the second electrode 40 includes sixth sub-electrodes 41 arranged at intervals in the first direction X, and an opening 42 is provided between two adjacent sixth sub-electrodes 41. An extension direction of the sixth sub-electrode 41 has a certain included angle with the second direction Y, and in the extension direction of the sixth sub-electrode 41, the sixth sub-electrode 41 is offset to the same side of the first direction X in sequence. For example, as shown in FIG. 13, in the extension direction of the sixth sub-electrode 41, the sixth sub-electrode 41 is offset to the left by a certain distance each time it extends downward by one row of pixel regions. An orthographic projection of a single sixth sub-electrode 41 on the substrate 101 partially overlaps with orthographic projections, on the substrate 101, of two first electrodes 30 adjacent to the sixth sub-electrode 41 in the first direction X, and the sixth sub-electrode 41 forms storage capacitors C1 with the two first electrodes 30. An orthographic projection of the opening 42 on the substrate 101 partially overlaps with the orthographic projection of the first electrode 30 on the substrate 101. For example, an orthographic projection, on the substrate 101, of the middle of the first electrode 30 in the first direction X overlaps with the orthographic projection of the opening 42 on the substrate 101. That is, the opening 42 exposes a partial region of the middle of the first electrode 30 in the first direction X.

In some embodiments, referring to FIG. 17, a line width D11 of the first signal line 10 is in a range of 1 μm to 2 μm. In this way, the line width of the first signal line 10 may be greatly reduced, which is beneficial to improving the pixel density of the array substrate. The line width of the first signal line 10 is a dimension of the first extension segment 13 in the second direction Y, and a dimension of the second extension segment 14 in the first direction X.

For example, a value of the line width D11 of the first signal line 10 ranges from 1 μm to 1.3 μm. For example, the value of the line width D11 of the first signal line 10 is 1 μm, 1.1 μm, 1.25 μm or 1.3 μm. Alternatively, the value of the line width D11 of the first signal line 10 ranges from 1.3 μm to 1.7 μm. For example, the line width D11 of the first signal line 10 is 1.3 μm, 1.45 μm, 1.6 μm or 1.7 μm. Alternatively, the value of the line width D11 of the first signal line 10 ranges from 1.7 μm to 2 μm. For example, the value of the line width D11 of the first signal line 10 is 1.7 μm, 1.85 μm, 1.9 μm or 2 μm. Of course, the value of the line width D11 of the first signal line 10 is not limited to these, and other values will not be listed in the embodiments of the present disclosure one by one.

Referring to FIG. 17, a dimension D12 of the first sub-portion 51 in the first direction X is in a range of 1 μm to 2.5 μm. Thus, it is beneficial for the first sub-portion 51 to completely cover the second extension segment 14 of the first signal line 10, thereby greatly improving the shielding effect of the first sub-portion 51 on the second extension segment 14, and reducing the magnitude of the capacitance of the parasitic capacitor between the second extension segment 14 and the first electrode 30.

For example, the dimension D12 of the first sub-portion 51 in the first direction X ranges from 1 μm to 1.5 μm. For example, the dimension D12 of the first sub-portion 51 in the first direction X is 1 μm, 1.25 μm, 1.4 μm or 1.5 μm. Alternatively, the dimension D12 of the first sub-portion 51 in the first direction X ranges from 1.5 μm to 2 μm. For example, the dimension D12 of the first sub-portion 51 in the first direction X is 1.5 μm, 1.65 μm, 1.8 μm or 2 μm. Alternatively, the dimension D12 of the first sub-portion 51 in the first direction X ranges from 2 μm to 2.5 μm. For example, the dimension D12 of the first sub-portion 51 in the first direction X is 2 μm, 2.25 μm, 2.4 μm or 2.5 μm. Of course, the dimension D12 of the first sub-portion 51 in the first direction X is not limited to these, and other values will not be listed in the embodiments of the present disclosure one by one.

Referring to FIGS. 18 and 19, a dimension D13 of the second sub-portion 52 in the second direction Y is in a range of 1 μm to 2 μm. Thus, the line width of the second sub-portion 52 is relatively small, which is beneficial to reducing the size of a portion of the second sub-portion 52 in the pixel region 102, and greatly reducing the influence of the second sub-portion 52 on the light extraction rate of the pixel region 102.

For example, the dimension D13 of the second sub-portion 52 in the second direction Y ranges from 1 μm to 1.3 μm. For example, the dimension D13 of the second sub-portion 52 in the second direction Y is 1 μm, 1.1 μm, 1.2 μm or 1.3 μm. Alternatively, the dimension D13 of the second sub-portion 52 in the second direction Y ranges from 1.3 μm to 1.7 μm. For example, the dimension D13 of the second sub-portion 52 in the second direction Y is 1.3 μm, 1.4 μm, 1.5 μm or 1.7 μm. Alternatively, the dimension D13 of the second sub-portion 52 in the second direction Y ranges from 1.7 μm to 2 μm. For example, the dimension D13 of the second sub-portion 52 in the second direction Y is 1.7 μm, 1.8 μm, 1.9 μm or 2 μm, which is not listed one by one in the embodiments of the present disclosure.

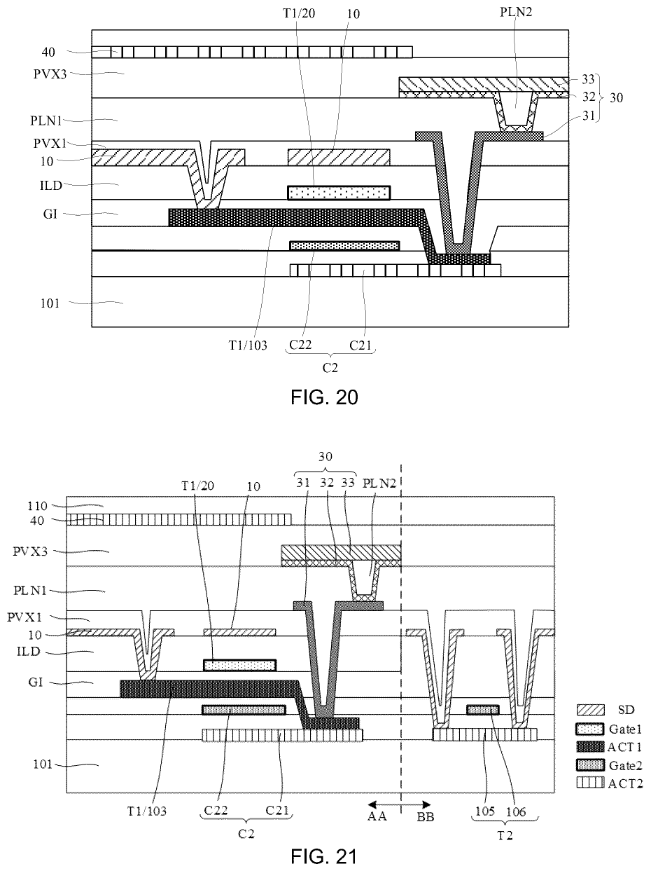

In some embodiments, referring to FIG. 20, the array substrate 100 further includes a plurality of first transistors T1 and a plurality of compensation capacitors C2. A single compensation capacitor C2 corresponds to one first transistor T1, and at least a portion of the compensation capacitor C2 is disposed on a side of the first transistor T1 close to the substrate 101.

A single first transistor T1 is electrically connected to one first electrode 30; a first electrode of the first transistor T1 is electrically connected to the first signal line 10, and a second electrode of the first transistor T1 is electrically connected to the first electrode 30. A first electrode plate C21 of the compensation capacitor C2 is electrically connected to the second electrode of the first transistor T1 (that is, the first electrode plate C21 of the compensation capacitor C2 is electrically connected to the first electrode 30), and a second electrode plate C22 of the compensation capacitor C2 is electrically connected to a constant voltage signal terminal. The compensation capacitor C2 can maintain the stability of the voltage of the first electrode 30, which is beneficial to reducing the voltage fluctuation of the first electrode 30, thereby reducing the fluctuation of the electric field formed between the first electrode 30 and the second electrode 40, and improving the display quality of the display panel.

In some embodiments, with continued reference to FIG. 20, the array substrate 100 further includes the second electrode 40, and the second electrode plate C22 of the compensation capacitor C2 transmits the same voltage signal as the second electrode 40. In this way, the compensation capacitor C2 and the storage capacitor C1 are connected in parallel, which may increase the total capacitance of the storage capacitor C1. It can be seen, from the above that

$$Δ V 1 = \frac{Cpd 1}{Cpd 1 + C 1} \times Δ Vdata 1 and Δ V 2 = \frac{Cpd 2}{Cpd 2 + C 1} \times Δ Vdata 2 ,$$

that the voltage generated by the coupling of the first signal line 10 and the first electrode 30 is ΔV, which is negatively correlated with the capacitance of the storage capacitor C1. The compensation capacitor C2 and the storage capacitor C1 are connected in parallel, which is beneficial to reducing the voltage (ΔV) generated by the coupling of the first electrode 30 with two adjacent first signal lines 10, thereby reducing the voltage fluctuation of the first electrode 30. That is, it may be possible to improve the voltage stability of the first electrode 30, thereby improving the display quality of the display panel.

In some embodiments, referring to FIG. 21, the array substrate 100 includes a display region AA and a peripheral region BB, and the first transistors T1 and the compensation capacitors C2 are disposed in the display region AA. The array substrate 100 further includes a second semiconductor layer ACT2 and a second gate layer Gate2 sequentially arranged in a direction away from the substrate 101. The second semiconductor layer ACT2 and the second gate layer Gate2 are both located on a side, close to the substrate 101, of film layers where the first transistors T1 are located.

A material of the second semiconductor layer ACT2 can include one or more of amorphous silicon, polysilicon, metal oxide material(s), and metal oxynitride material(s). The metal oxide material(s) include, but are not limited to: one or more of indium gallium zinc oxide (IGZO), indium gallium tin oxide (IGTO), indium tin zinc oxide (ITZO), indium gallium oxide (IGO), indium gallium zinc tin oxide (IGZTO), indium zinc oxide (IZO), zinc tin oxide (ZTO), indium-free metal oxide (In-free OS), rare earth doped oxide (Ln-OS), zinc oxide (ZnO), gallium oxide (GaO), indium oxide (InO), HflnZnO (HIZO), ZnO:F, In₂O₃:Sn, In₂O₃:Mo, Cd₂SnO₄, ZnO:AI, TiO₂:Nb, and Cd—Sn—O.

The metal oxynitride material(s) include, but are not limited to: at least one of zinc oxynitride, indium oxynitride, gallium oxynitride, tin oxynitride, cadmium oxynitride, aluminum oxynitride, germanium oxynitride, titanium oxynitride, and silicon oxynitride. The polysilicon may include low temperature polysilicon (LTPS).

The material of the second semiconductor layer ACT2 may be in an amorphous state, a partially crystalline state, a single crystal state or a polycrystalline state, and may be of a single layer or multi-layer structure.

The array substrate 100 further includes a plurality of second transistors T2 disposed in the peripheral region BB. For example, the plurality of second transistors T2 are configured to form a gate driving circuit (gate on array, GOA). The second transistor T2 includes a second semiconductor pattern 105 located in the second semiconductor layer ACT2 and a second gate pattern 106 located in the second gate layer Gate2.

The first electrode plate C21 of the compensation capacitor C2 is located in the second semiconductor layer ACT2, and the second electrode plate C22 of the compensation capacitor C2 is located in the second gate layer Gate2. Based on this, the first electrode plate C21 of the compensation capacitor C2 may be formed simultaneously in a process of manufacturing the second semiconductor layer ACT2, and the second electrode plate C22 of the compensation capacitor C2 may be formed simultaneously in a process of manufacturing the second gate layer Gate2. In this way, the manufacturing process of the compensation capacitor C2 may be greatly simplified, and the manufacturing cost of the compensation capacitor C2 may be reduced.

Of course, the embodiments of the present disclosure are not limited to this, as long as the same technical concept is adopted. For example, at least one of the first electrode plate C21 and the second electrode plate C22 of the compensation capacitor C2 can also be manufactured by other film layer(s). For example, one or two new film layers can be added on the side of the first transistor T1 close to the substrate 101 to manufacture the first electrode plate C21 and/or the second electrode plate C22.

In some embodiments, the second transistor T2 can be a low temperature polysilicon thin film transistor (LTPS TFT). The low temperature polysilicon thin film transistor has advantages such as high mobility and high response speed, which is beneficial to improving the response speed of the gate driving circuit.

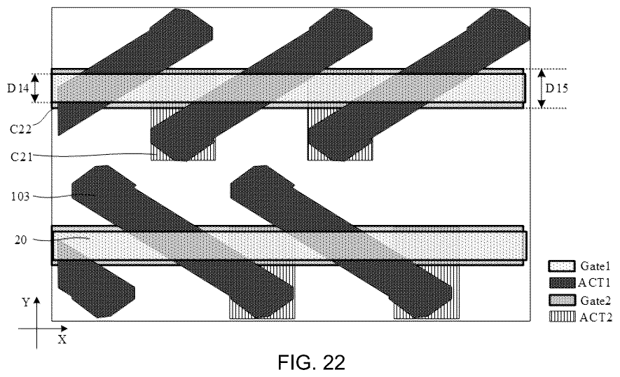

In some embodiments, referring to FIG. 22, the second electrode plate C22 of the compensation capacitor C2 extends in the first direction X, and an orthographic projection of the second electrode plate C22 on the substrate 101 at least partially overlaps with an orthographic projection of the second signal line 20 on the substrate 101. The second electrode plate C22 extends in the first direction X, and it is beneficial for the second electrode plate C22 to extend to the peripheral region BB and to be electrically connected to the constant voltage signal terminal (common voltage signal terminal). In addition, the orthographic projection of the second electrode plate C22 on the substrate 101 at least partially overlaps with the orthographic projection of the second signal line 20 on the substrate 101, which is beneficial to reducing the area of a portion of the second electrode plate C22 located in the pixel region 102, thereby reducing the influence of the second electrode plate C22 on the light transmittance of the pixel region 102, and improving the light transmittance of the array substrate.

In some embodiments, a dimension D14 of the second signal line 20 in the second direction is in a range of 1 μm to 2 μm. In this way, the line width of the second signal line 20 may be greatly reduced, which is beneficial to improving the aperture ratio of the pixel region 102, thereby improving the pixel density of the array substrate.

For example, the dimension D14 of the second signal line 20 in the second direction ranges from 1 μm to 1.3 μm. For example, the dimension D14 of the second signal line 20 in the second direction is 1 μm, 1.1 μm, 1.2 μm or 1.3 μm. Alternatively, the dimension D14 of the second signal line 20 in the second direction ranges from 1.3 μm to 1.7 μm. For example, the dimension D14 of the second signal line 20 in the second direction is 1.3 μm, 1.5 μm, 1.6 μm or 1.7 μm. Alternatively, the dimension D14 of the second signal line 20 in the second direction ranges from 1.7 μm to 2 μm. For example, the dimension D14 of the second signal line 20 in the second direction is 1.7 μm, 1.8 μm, 1.9 μm or 2.0 μm. Of course, the dimension D14 of the second signal line 20 in the second direction is not limited to these, and other values will not be listed in the embodiments of the present disclosure one by one.

In some embodiments, a dimension D15 of the second electrode plate C22 in the second direction Y is in a range of 1 μm to 3 μm.

For example, the dimension D15 of the second electrode plate C22 in the second direction Y is in a range of 1 μm to 2 μm. In this case, the second electrode plate C22 has a relatively small line width, which may greatly reduce the line width of the second electrode plate C22, thereby helping to improve the aperture ratio of the pixel region 102 and improving the pixel density of the array substrate. For example, the dimension D15 of the second electrode plate C22 in the second direction Y is 1 μm, 1.3 μm, 1.5 μm, 1.8 μm or 2 μm, which will not be listed one by one in the embodiments of the present disclosure.

For example, the dimension D15 of the second electrode plate C22 in the second direction Y is in a range of 2 μm to 3 μm. In this case, the orthographic projection of the second electrode plate C22 on the substrate 101 covers the orthographic projection of the second signal line 20 on the substrate 101, and covers the orthographic projection of the channel region of the first semiconductor pattern 103 of the first transistor T1 on the substrate 101. That is, the second electrode plate C22 can block the channel region of the first semiconductor pattern 103 of the first transistor T1. Thus, the light entering the channel region of the first semiconductor pattern 103 of the first transistor T1 is reduced, and the stability of the first transistor T1 under backlight irradiation is improved. For example, the dimension D15 of the second electrode plate C22 in the second direction Y is 2 μm, 2.4 μm, 2.5 μm, 2.7 μm or 3 μm, which will not be listed one by one in the embodiments of the present disclosure.

The foregoing descriptions are merely specific implementations of the present disclosure, but the protection scope of the present disclosure is not limited thereto, any changes or replacements that a person skilled in the art could conceive of within the technical scope of the present disclosure shall be included in the protection scope of the present disclosure. Therefore, the protection scope of the present disclosure should be determined by the protection scope of the claims.

1. An array substrate, comprising:
a substrate, and a plurality of first signal lines and a plurality of second signal lines located on a side of the substrate, wherein the plurality of first signal lines and the plurality of second signal lines cross to define a plurality of pixel regions; the plurality of first signal lines are arranged at intervals in a first direction, portions of a first signal line are bent in a second direction, and the first signal line includes first portions and second portions; a side of each pixel region is provided with a first portion of one first signal line, another side of the pixel region is provided with a second portion of another first signal line, and a length of the first portion is greater than a length of the second portion; wherein the first direction and the second direction intersect; and
a plurality of first electrodes corresponding to the plurality of pixel regions, wherein at least a portion of a first electrode is located in a corresponding pixel region; in orthographic projections of the first electrode, the first portion and the second portion on the substrate, a distance between at least the portion of the first electrode and the first portion in the first direction is not equal to a distance between the first electrode and the second portion in the first direction.

2. The array substrate according to claim 1, wherein in the orthographic projections of the first electrode, the first portion and the second portion on the substrate, a length of a side, opposite to the first portion, of the first electrode is greater than a length of a side, opposite to the second portion, of the first electrode, and the distance between at least the portion of the first electrode and the first portion in the first direction is greater than the distance between the first electrode and the second portion in the first direction.

3. The array substrate according to claim 1, wherein
the first signal line includes a plurality of first extension segments and a plurality of second extension segments that are alternately connected; the plurality of first extension segments extend in the first direction and are arranged at intervals in the second direction; the plurality of second extension segments extend in the second direction, and any two adjacent second extension segments in the plurality of second extension segments are connected to two ends of a first extension segment in the first direction;
the first portion includes one second extension segment and two first extension segments connected to the second extension segment, and the second portion includes one second extension segment close to the first portion; the second extension segment included in the first portion is a first sub-segment, and the second extension segment included in the second portion is a second sub-segment; and
in orthographic projections of the first electrode, the first sub-segment and the second sub-segment on the substrate, a distance between at least the portion of the first electrode and the first sub-segment in the first direction is greater than a distance between at least the portion of the first electrode and the second sub-segment in the first direction.

4. The array substrate according to claim 3, further comprising:
a plurality of first transistors, wherein a first transistor is electrically connected to one first electrode; a first electrode of the first transistor is electrically connected to the first signal line, and a second electrode of the first transistor is electrically connected to the first electrode, wherein
the first electrode includes a first sub-electrode, a second sub-electrode, and a third sub-electrode that are arranged in a direction away from the substrate; the first sub-electrode is electrically connected to the second electrode of the first transistor, the second sub-electrode is electrically connected to the first sub-electrode, and the third sub-electrode is electrically connected to the second sub-electrode; and
a distance between an orthographic projection of at least a portion of at least one of the first sub-electrode, the second sub-electrode and the third sub-electrode on the substrate and an orthographic projection of the first sub-segment on the substrate in the first direction is greater than a distance between the orthographic projection of at least the portion of the at least one of the first sub-electrode, the second sub-electrode and the third sub-electrode on the substrate and an orthographic projection of the second sub-segment on the substrate in the first direction.

5. The array substrate according to claim 34, wherein the first sub-electrode includes:
a third portion, wherein in orthographic projections of the third portion, the first sub-segment and the second sub-segment on the substrate, a distance between the third portion and the first sub-segment in the first direction is greater than a distance between the third portion and the second sub-segment in the first direction; and
a fourth portion, wherein the fourth portion is located on a side of the third portion in the second direction and is connected to the third portion; an edge of the fourth portion close to the first sub-segment is flush with an edge of the third portion close to the first sub-segment, and an edge of the fourth portion close to the second sub-segment extends out of an edge of the third portion.

6. The array substrate according to claim 5, wherein an orthographic projection of the fourth portion on the substrate at least partially overlaps with the orthographic projection of the second sub-segment on the substrate.

7. (canceled)

8. The array substrate according to claim 4, wherein the second sub-electrode includes:
a fifth portion, wherein in orthographic projections of the fifth portion, the first sub-segment and the second sub-segment on the substrate, a distance between the fifth portion and the first sub-segment in the first direction is equal to a distance between the fifth portion and the second sub-segment in the first direction; and
a sixth portion, wherein the sixth portion is located on a side of the fifth portion in the second direction and is connected to the fifth portion; two ends of the sixth portion in the first direction extend out of edges of the fifth portion, and a distance between an orthographic projection of the sixth portion on the substrate and the orthographic projection of the first sub-segment on the substrate in the first direction is greater than a distance between the orthographic projection of the sixth portion on the substrate and the orthographic projection of the second sub-segment on the substrate in the first direction; and/or
in orthographic projections of the third sub-electrode, the first sub-segment and the second sub-segment on the substrate, borders, close to each other, of the third sub-electrode and the first sub-segment are approximately parallel, and borders, close to each other, of the third sub-electrode and the second sub-segment are approximately parallel; and a distance between the third sub-electrode and the first sub-segment in the first direction is greater than a distance between the third sub-electrode and the second sub-segment in the first direction.

9-11. (canceled)

12. The array substrate according to claim 4, further comprising:
a first semiconductor layer, a first insulating layer, a first gate conductive layer, a second insulating layer, a source-drain conductive layer and a third insulating layer that are arranged in a direction away from the substrate, wherein the first transistor includes a first semiconductor pattern located in the first semiconductor layer and a first gate pattern located in the first gate conductive layer; and the plurality of first signal lines are arranged in the source-drain conductive layer;
first via holes penetrating through the first insulating layer and the second insulating layer, wherein the first signal line passes through a first via hole to be electrically connected to the first semiconductor pattern;
second via holes penetrating through the first insulating layer, the second insulating layer and the third insulating layer, wherein the first sub-electrode passes through a second via hole to be electrically connected to the first semiconductor pattern;
a first planarization layer disposed between the first sub-electrode and the second sub-electrode, wherein the first planarization layer includes third via holes, a third via hole exposes a portion of the first sub-electrode, and the second sub-electrode passes through the third via hole to be electrically connected to the first sub-electrode; and
a second planarization layer disposed on a side of the second sub-electrode away from the substrate, wherein the second planarization layer covers a portion of the second sub-electrode located in the third via hole and exposes at least a portion of the second sub-electrode located on the first planarization layer, wherein
the third sub-electrode covers the second planarization layer and at least a portion of the second sub-electrode.

13. (canceled)

14. The array substrate according to claim 1, further comprising:
a first auxiliary layer disposed between a layer where the plurality of first signal lines are located and a layer where the plurality of first electrodes are located, wherein
in orthographic projections of the first auxiliary layer, the first signal line and the first electrode on the substrate, the first auxiliary layer at least partially overlaps with the first signal line, and/or the first auxiliary layer at least partially overlaps with the first electrode.

15. The array substrate according to claim 14, wherein
an orthographic projection of the first auxiliary layer on the substrate covers an orthographic projection of the first signal line on the substrate, and is non-overlapping with at least a portion of an orthographic projection of the first electrode on the substrate.

16. The array substrate according to claim 15, wherein
the first signal line includes a plurality of first extension segments and a plurality of second extension segments that are alternately connected; and
the first auxiliary layer is of a grid structure, and the first auxiliary layer includes:
a plurality of first sub-portions extending in the second direction, wherein an orthographic projection of a first sub-portion on the substrate covers an orthographic projection of one second extension segment on the substrate;
a plurality of second sub-portions extending in the first direction, wherein an orthographic projection of a second sub-portion on the substrate covers orthographic projections, on the substrate, of multiple first extension segments that are arranged in the first direction and in different first signal lines; and
a plurality of grid holes, wherein a grid hole corresponds to one pixel region, and the grid hole exposes at least a portion of the pixel region corresponding to the grid hole.

17. The array substrate according to claim 16, further comprising:
a second electrode disposed on a side of the first electrode away from the substrate, wherein first auxiliary layer and the second electrode transmit a same voltage signal; or
the array substrate further comprising;
a second electrode disposed on a side of the first electrode away from the substrate, wherein first auxillary layer and the second electrode transmit a same voltage signal, and the orthographic projection of the first auxillary layer on the substrate at least partially overlaps with an orthographic projection of the second electrode on the substrate.

18. (canceled)

19. The array substrate according to claim 17, wherein
in orthographic projections of the second electrode and the first sub-portion on the substrate, the second electrode covers the first sub-portion, and there is an interval between a border of the second electrode and a border of the first sub-portion; and
the orthographic projection of the second electrode on the substrate partially overlaps with an orthographic projection of the second sub-portion on the substrate.

20. (canceled)

21. The array substrate according to claim 14, further comprising:
a plurality of first transistors, wherein a first transistor is electrically connected to one first electrode; a first electrode of the first transistor is electrically connected to the first signal line, and a second electrode of the first transistor is electrically connected to the first electrode, wherein
the first electrode includes a fourth sub-electrode and a fifth sub-electrode arranged in sequence in a direction away from the substrate, the fourth sub-electrode is electrically connected to the second electrode of the first transistor, and the fifth sub-electrode is electrically connected to the fourth sub-electrode.

22. The array substrate according to claim 21, further comprising:
a first semiconductor layer, a first insulating layer, a first gate conductive layer, a second insulating layer, a source-drain conductive layer, a third insulating layer, a first planarization layer and a fourth insulating layer that are arranged in a direction away from the substrate, wherein the first transistor includes a first semiconductor pattern located in the first semiconductor layer and a first gate pattern located in the first gate conductive layer; and the plurality of first signal lines are arranged in the source-drain conductive layer;
first via holes penetrating through the first insulating layer and the second insulating layer, wherein the first signal line passes through a first via hole to be electrically connected to the first semiconductor pattern;
fourth via holes penetrating through the first insulating layer, the second insulating layer, the third insulating layer, the first planarization layer and the fourth insulating layer, wherein the fourth sub-electrode passes through a fourth via hole to be electrically connected to the first semiconductor pattern; and
a second planarization layer disposed on a side of the fourth sub-electrode away from the substrate, wherein the second planarization layer covers a portion of the fourth sub-electrode in the fourth via hole, and exposes at least a portion of the fourth sub-electrode on the fourth insulating layer, wherein
the first auxiliary layer is disposed between the first planarization layer and the fourth insulating layer; and the fifth sub-electrode covers the second planarization layer and at least a portion of the fourth sub-electrode.

23. The array substrate according to claim 1, wherein the array substrate further comprises;
a plurality of first transistors, wherein a first transistor is electrically connected to one first electrode; a first electrode of the first transistor is electrically connected to the first signal line, and a second electrode of the first transistor is electrically connected to the first electrode; and
a plurality of compensation capacitors, wherein at least a portion of a compensation capacitor is disposed on a side of the first transistor close to the substrate; a first electrode plate of the compensation capacitor is electrically connected to the second electrode of the first transistor, and a second electrode plate of the compensation capacitor is electrically connected to a constant voltage signal terminal.

24. The array substrate according to claim 23, further comprising:
a second electrode disposed on a side of the first electrode away from the substrate, wherein
the second electrode plate of the compensation capacitor transmits a same voltage signal as the second electrode.

25. The array substrate according to claim 24, wherein the array substrate comprises a display region and a peripheral region, and the plurality of first transistors are disposed in the display region, and the array substrate further comprises:
a second semiconductor layer and a second gate layer arranged in a direction away from the substrate, wherein the second semiconductor layer and the second gate layer are located on a side of the plurality of first transistors close to the substrate; and
second transistors disposed in the peripheral region, wherein a second transistor includes a second semiconductor pattern located in the second semiconductor layer and a second gate pattern located in the second gate layer, wherein
the first electrode plate of the compensation capacitor is located in the second semiconductor layer, and the second electrode plate of the compensation capacitor is located in the second gate layer.

26. (canceled)

27. The array substrate according to claim 23, wherein
the second electrode plate of the compensation capacitor extends in the first direction, and an orthographic projection of the second electrode plate on the substrate at least partially overlaps with an orthographic projection of a second signal line on the substrate.

28. (canceled)

29. A display panel, comprising:
the array substrate according to claim 1;
an opposite substrate disposed opposite to the array substrate; and
a liquid crystal layer disposed between the array substrate and the opposite substrate.
